(19) United States
(12) Patent Application Publication
(10) Pub. No.: US 2013/0070385 A1
(43) Pub. Date: Mar. 21, 2013

(54) STACKED STRUCTURE AND METHOD OF MANUFACTURING THE SAME

(71) Applicants: Gaku Harada, Kawanishi-shi (JP); Miwa Ogawa, Hirakata-shi (JP); Kaori Ishikawa, Nishinomiya-shi (JP)

(72) Inventors: Gaku Harada, Kawanishi-shi (JP); Miwa Ogawa, Hirakata-shi (JP); Kaori Ishikawa, Nishinomiya-shi (JP)

(73) Assignee: SANYO ELECTRIC CO., LTD., Osaka (JP)

(21) Appl. No.: 13/610,035

(22) Filed: Sep. 11, 2012

(30) Foreign Application Priority Data
Sep. 15, 2011 (JP) 2011-201889
Sep. 23, 2011 (JP) 2011-208228

(51) Int. Cl. H01G 4/30; H05K 3/10

(52) U.S. Cl. 361/301.4; 29/846

(57) ABSTRACT

A stacked structure includes: first and second electrode parts, and a dielectric layer. The first electrode part has a first strip portion and a plurality of first plate portions extending from a side edge of the first strip portion. The second electrode part has a second strip portion and a plurality of second plate portions extending from a side edge of the second strip portion. The first and second electrode parts are arranged such that the first and second plate portions are stacked. The first plate portions face the second plate portions and the second strip portion. The second plate portions face the first plate portions and the first strip portion. The dielectric layer is placed between the first plate portions and adjacent ones of the second plate portions, between the first plate portions and the second strip portion, and between the second plate portions and the first strip portion.

### INCORPORATION BY REFERENCE

Japanese patent application Numbers 2011-201889 and 2011-208228, upon which this patent application is based, are hereby incorporated by reference.

### BACKGROUND OF THE INVENTION

1. Field of the Invention

The invention relates to a stacked structure having a characteristic electrode structure and a method of manufacturing the same.

2. Description of Related Art

A stacked capacitor such as a ceramic capacitor and a film capacitor includes a stacked structure functioning as a capacitor. A conventional stacked structure is composed of a stack of anode foils and cathode foils arranged one by one alternately while a dielectric layer is placed between the anode foils and cathode foils.

For manufacture of the conventional stacked structure, a metal foil is die-cut into predetermined shapes to form anode foils and cathode foils, and thereafter, the anode foils and the cathode foils are handled separately to stack the anode foils and the cathode foils one by one alternately.

In the conventional stacked structure, the cathode foils are electrically connected to a cathode collector, whereas the anode foils are spaced apart from the cathode collector in order to avoid electrical short of the anode foils with the cathode collector. Further, the anode foils are electrically connected to an anode collector, whereas the cathode foils are spaced apart from the anode collector in order to avoid electrical short of the cathode foils with the anode collector. This makes parts (non-facing parts) of the anode foils and the cathode foils not face each other. So, a region occupied by the anode and cathode collectors and a region occupied by the non-facing parts are formed in the conventional stacked structure. Thus, reduction in electrostatic capacitance per unit volume has been unavoidable due to the presence of these regions.

Meanwhile, further size reduction and further capacitance increase of a stacked structure has been desired in recent years in response to size reduction and higher performance of an electronic device to be mounted with the stacked capacitor. Conventionally, multi-layering technique or thinning technique has been employed effectively for size reduction and capacitance increase of a stacked structure. However, it has become impossible in recent years to achieve significant advances in these techniques.

Further, handling anode foils and cathode foils separately as has been done conventionally complicates manufacturing process of a stacked structure. Additionally, if the number of anode foils and cathode foils to be stacked is increased, process of stacking the anode foils and the cathode foils takes a long time to reduce manufacturing efficiency of the stacked structure.

So, technique described next has been suggested as an example. First, an anode foil of a certain shape and a cathode foil of a certain shape are prepared. The anode foil is composed of a first strip portion, and a plurality of first plate portions extending in the form of comb teeth from a side edge of the first strip portion. The cathode foil is composed of a second strip portion, and a plurality of second plate portions extending in the form of comb teeth from a side edge of the second strip portion. Next, dielectric layers are formed on surfaces of both the first and second plate portions. Then, the cathode foil is arranged with respect to the anode foil such that the second plate portions overlap the first plate portions one by one from the same direction. Next, the first and second strip portions are folded together in a bellows shape, so that the first plate portions and the second plate portions are stacked. In the stacked structure thereby formed, the first and second strip portions constitute anode and cathode collectors respectively.

This technique allows easy handling of the anode and cathode foils to increase manufacturing efficiency of the stacked structure. This technique also realizes arrangement of the anode and cathode foils in a manner that allows reduction of the non-facing parts.

Meanwhile, the first and second strip portions function as the anode and cathode collectors respectively and partially occupies the region of the stacked structure. So, an electrostatic capacitance per unit volume cannot be increased significantly.

Additionally, two first plate portions and two second plate portions are stacked alternately in inner layers (layers except the top layer and the bottom layer) (see FIG. 48). So, the number of electrode pairs each of which forms a capacitor element is reduced by about half, compared to a structure where first plate portions and second plate portions are stacked one by one alternately. This reduces an electrostatic capacitance per unit volume of the stacked structure.

According to technique suggested in relation to the aforementioned technique, the number of times the first and second strip portions are folded is doubled or increased more in order to stack the first plate portions and the second plate portions one by one alternately. However, this requires longer time for folding during process of folding the first and second strip portions in a bellows shape as a result of increase of the number of times of folding, resulting in reduction of manufacturing efficiency of the stacked structure.

### SUMMARY OF THE INVENTION

A first stacked structure of the invention includes a first electrode part, a second electrode part, and a dielectric layer. The first electrode part has a first strip portion and a plurality of first plate portions extending from a side edge of the first strip portion. The second electrode part has a second strip portion and a plurality of second plate portions extending from a side edge of the second strip portion. The first and second electrode parts are arranged such that the first plate portions and the second plate portions are stacked. The first plate portions face the second plate portions and the second strip portion, and the second plate portions face the first plate portions and the first strip portion. The dielectric layer is placed between the first plate portions and adjacent ones of the second plate portions, between the first plate portions and the second strip portion, and between the second plate portions and the first strip portion.

A method of manufacturing the first stacked structure of the invention includes steps (a) to (e). In the step (a), a first electrode sheet with a first strip portion and a plurality of first plate portions extending in the form of comb teeth from a side edge of the first strip portion is formed. In the step (b), a second electrode sheet with a second strip portion and a plurality of second plate portions extending in the form of comb teeth from a side edge of the second strip portion is formed. In the step (c), a dielectric layer is formed on surfaces of at least the first plate portions or the second plate portions, and on a surface of at least the first or second strip portion. The step (d) is performed after the steps (a) to (c). In the step (d), the first and second electrode sheets are made to overlap each other. In the step (d), the arrangement of the second electrode sheet with respect to the first electrode sheet is determined such that the second plate portions overlap the first plate portions, and that regarding each of the first plate portions and one of the second plate portions to overlap this first plate portion, part of this first plate portion overlaps the second strip portion and part of this second plate portion overlaps the first strip portion. The step (e) is performed after the step (d). In the step (e), the first and second strip portions are folded together in a bellows shape or a spiral shape to stack the first plate portions and the second plate portions.

A second stacked structure of the invention includes a first electrode part, a second electrode part, and a dielectric layer. The first electrode part has a first strip portion and a plurality of first plate portions extending from a side edge of the first strip portion. The second electrode part has a second strip portion and a plurality of second plate portions extending from a side edge of the second strip portion. The first and second strip portions each have a bellows shape or a spiral shape. The first and second electrode parts are arranged such that the first plate portions and the second plate portions are stacked one by one alternately. The dielectric layer is placed between the first plate portions and adjacent ones of the second plate portions. The first strip portion has a plurality of first flat sections. Each of the first plate portions extends from a corresponding one of the first flat sections, whereas the first strip portion is not placed between any two of the first flat sections adjacent to each other. The second strip portion has a plurality of second flat sections. Each of the second plate portions extends from a corresponding one of the second flat sections, whereas the second strip portion is not placed between any two of the second flat sections adjacent to each other.

A method of manufacturing the second stacked structure of the invention includes steps (a) to (e). In the step (a), a first electrode sheet with a first strip portion and a plurality of first plate portions extending in the form of comb teeth from a side edge of the first strip portion is formed. In the step (b), a second electrode sheet with a second strip portion and a plurality of second plate portions extending in the form of comb teeth from a side edge of the second strip portion is formed. In the step (c), a dielectric layer is formed on surfaces of at least the first plate portions or the second plate portions. The step (d) is performed after the steps (a) to (c). In the step (d), the first and second electrode sheets are made to overlap each other. In the step (d), the arrangement of the second electrode sheet with respect to the first electrode sheet is determined such that the second plate portions overlap the first plate portions one by one, and that upper and lower positions of the first plate portions and the second plate portions with respect to each other are changed alternately in a longitudinal direction of the first or second strip portion. The step (e) is performed after the step (d). In the step (e), the first and second strip portions are folded together in a bellows shape to place each of the first plate portions and a corresponding one of the second plate portions one above the other in facing positions, this first plate portion and the corresponding second plate portion having been adjacent to each other in the longitudinal direction.

A different method of manufacturing the second stacked structure of the invention includes steps (a) to (e). In the step (a), a first electrode sheet with a first strip portion and a plurality of first plate portions extending in the form of comb teeth from a side edge of the first strip portion is formed. In the step (b), a second electrode sheet with a second strip portion and a plurality of second plate portions extending in the form of comb teeth from a side edge of the second strip portion is formed. In the step (c), a dielectric layer is formed on surfaces of at least the first plate portions or the second plate portions. The step (d) is performed after the steps (a) to (c). In the step (d), the first and second electrode sheets are made to overlap each other. In the step (d), the arrangement of the second electrode sheet with respect to the first electrode sheet is determined such that none of the second plate portions overlaps one of the first plate portions closest to one edge of the first strip portion in a longitudinal direction of the first strip portion, and that the second plate portions overlap the other first plate portions one by one. The step (e) is performed after the step (d). In the step (e), the first and second strip portions are folded together in a spiral shape, so that the first plate portion with no second plate portion thereon is first placed on an adjacent one of the second plate portions, and then the first plate portions are successively placed on adjacent ones of the second plate portions.

### BRIEF DESCRIPTION OF THE DRAWINGS

FIG. 1 is a perspective view of a stacked capacitor of a first embodiment;

FIG. 2 is a perspective view of a stacked structure of the stacked capacitor of the first embodiment;

FIG. 3 is a sectional view taken along line III-III of FIG. 2;

FIG. 4 is a sectional view taken along line IV-IV of FIG. 2;

FIG. 5 is a sectional view taken along line V-V of FIG. 2;

FIG. 6 is a plan view used for explanation of an electrode sheet forming step performed by a method of manufacturing the stacked capacitor of the first embodiment;

FIG. 7 is a view used for explanation of a dielectric layer forming step performed by the manufacturing method of the first embodiment;

FIG. 8 is a plan view showing a dielectric layer formed in this dielectric layer forming step;

FIG. 9 is a plan view used for explanation of an overlapping step performed by the manufacturing method of the first embodiment;

FIG. 10 is a perspective view of a stacked structure of a stacked capacitor of a second embodiment;

FIG. 11 is a sectional view taken along line XI-XI of FIG. 10;

FIGS. 12A and 12B are plan views used for explanation of an overlapping step performed by a method of manufacturing the stacked capacitor of the second embodiment;

FIG. 13 is a side view used for explanation of a folding step performed by the manufacturing method of the second embodiment;

FIG. 14 is a perspective view of a stacked structure of a stacked capacitor of a third embodiment;

FIG. 15 is a sectional view taken along line XV-XV of FIG. 14;

FIG. 16 is a plan view used for explanation of an electrode sheet forming step performed by a method of manufacturing the stacked capacitor of the third embodiment;

FIG. 17 is a plan view used for explanation of a dielectric layer forming step performed by the manufacturing method of the third embodiment;

FIG. 18 is a plan view used for explanation of an overlapping step performed by the manufacturing method of the third embodiment;

FIG. 19 is a perspective view of a stacked structure of a stacked capacitor of a fourth embodiment;

FIG. 20 is a sectional view taken along line XX-XX of FIG. 19;

FIGS. 21A and 21B are plan views used for explanation of an electrode sheet forming step performed by a method of manufacturing the stacked capacitor of the fourth embodiment;

FIGS. 22A and 22B are plan views used for explanation of a dielectric layer forming step performed by the manufacturing method of the fourth embodiment;

FIG. 23 is a plan view used for explanation of an overlapping step performed by the manufacturing method of the fourth embodiment;

FIG. 24 is a plan view used for explanation of a folding step performed by the manufacturing method of the fourth embodiment;

FIG. 25 is a perspective view of a stacked structure of a stacked capacitor of a fifth embodiment;

FIG. 26 is a sectional view taken along line XXVI-XXVI of FIG. 25;

FIG. 27 is a sectional view taken along line XXVII-XXVII of FIG. 25;

FIG. 28 is a sectional view taken along line XXVIII-XXVIII of FIG. 25;

FIG. 29 is a view used for explanation of a dielectric layer forming step performed by a method of manufacturing the stacked capacitor of the fifth embodiment;

FIG. 30 is a plan view showing a dielectric layer formed in this dielectric layer forming step;

FIG. 31 is a plan view used for explanation of an overlapping step performed by the manufacturing method of the fifth embodiment;

FIG. 32 is a perspective view of a stacked structure of a stacked capacitor of a sixth embodiment;

FIGS. 33A and 33B are plan views used for explanation of a dielectric layer forming step performed by a method of manufacturing the stacked capacitor of the sixth embodiment;

FIG. 34 is a plan view used for explanation of an overlapping step performed by the manufacturing method of the sixth embodiment;

FIGS. 35A and 35B are perspective views of a stacked capacitor of a first modification when the stacked capacitor is seen from obliquely above and obliquely below respectively;

FIG. 36 is a sectional view of a stacked structure of a stacked capacitor of a second modification;

FIG. 37 is a plan view used for explanation of an overlapping step performed by a method of manufacturing the stacked capacitor of the second modification;

FIGS. 38A and 38B are perspective views of a stacked capacitor of a third modification when the stacked capacitor is seen from obliquely above and obliquely below respectively;

FIG. 39 is a plan view used for explanation of an electrode sheet forming step and a masking step performed by a method of manufacturing the stacked capacitor of the third modification;

FIG. 40 is a view used for explanation of a dielectric layer forming step performed by the manufacturing method of the third modification;

FIG. 41 is a plan view showing a dielectric layer formed in this dielectric layer forming step;

FIG. 42 is a plan view used for explanation of an overlapping step performed by the manufacturing method of the third modification;

FIG. 43 is a perspective view of a stacked structure of a stacked capacitor of a fourth modification;

FIG. 44 is a plan view used for explanation of an electrode sheet forming step performed by a method of manufacturing the stacked capacitor of the fourth modification;

FIG. 45 is a perspective view of a different example of the stacked structure of the stacked capacitor of the fourth modification;

FIG. 46 is a view used for explanation of a dielectric layer forming step performed by a method of manufacturing a stacked capacitor of each of Comparative Examples 1 and 2;

FIG. 47 is a plan view used for explanation of an overlapping step performed by the method of manufacturing the stacked capacitor of each of Comparative Examples 1 and 2;

FIG. 48 is a sectional view of a stacked structure of the stacked capacitor of Comparative Example 1; and

FIG. 49 is a sectional view of a stacked structure of the stacked capacitor of Comparative Example 2.

### DETAILED DESCRIPTION OF THE EMBODIMENTS

### 1. First Embodiment

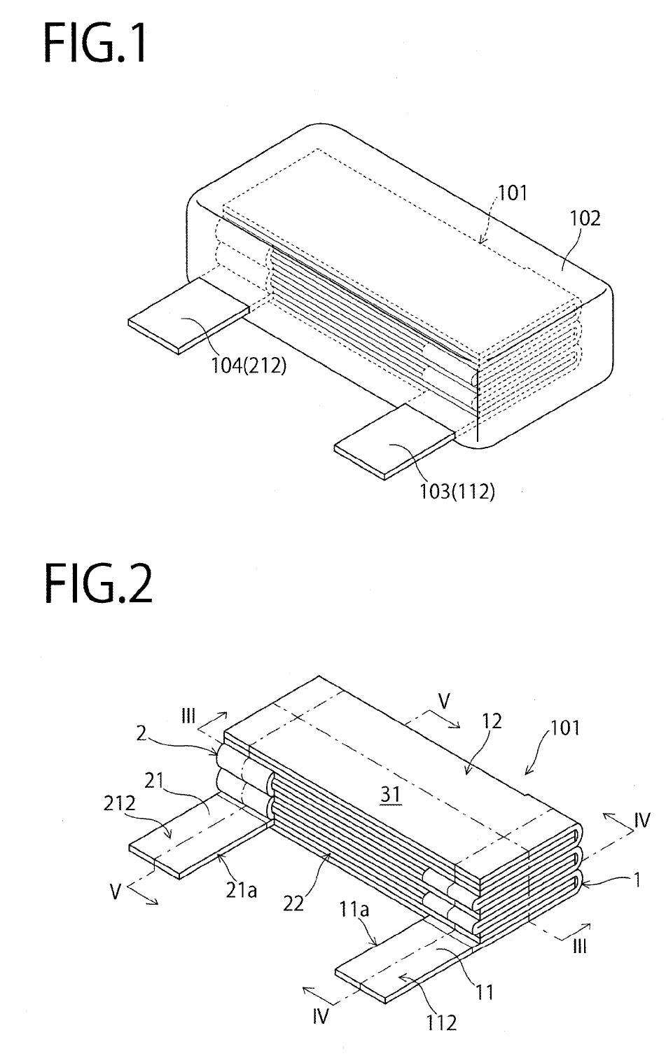

FIG. 1 is a perspective view of a stacked capacitor of a first embodiment. As shown in FIG. 1, the stacked capacitor includes a stacked structure 101 functioning as a capacitor, and an outer package 102 covering the stacked structure 101. The stacked structure 101 is given an anode terminal 103 and a cathode terminal 104 pulled out of the outer package 102. The outer package 102 is composed of a laminated film to seal the stacked structure 101 under vacuum. The outer package 102 may be molded with an electrically insulating material such as an epoxy resin to cover the stacked structure 101. These are not the only structures of the stacked capacitor, but the stacked capacitor may not include the outer package 102.

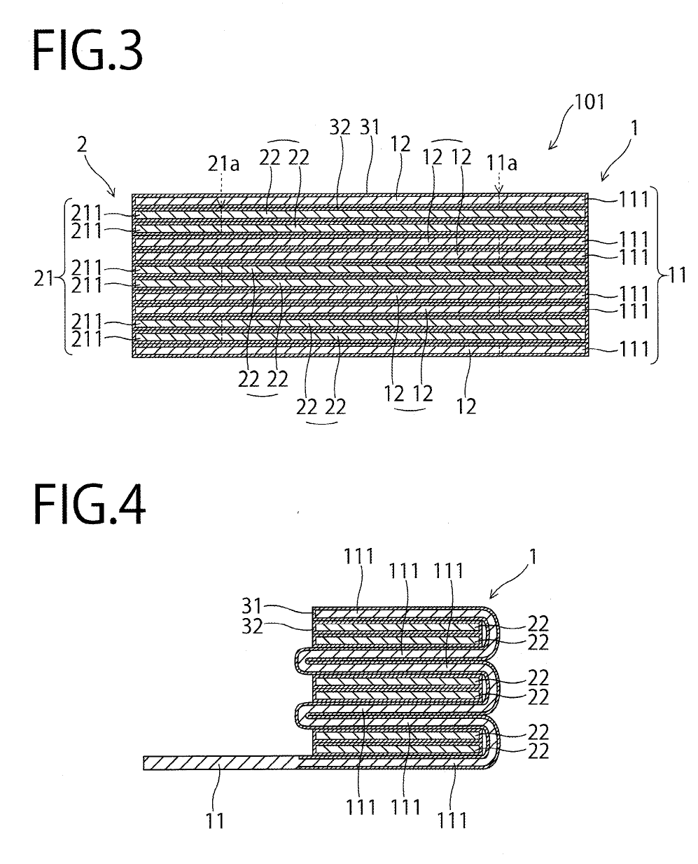

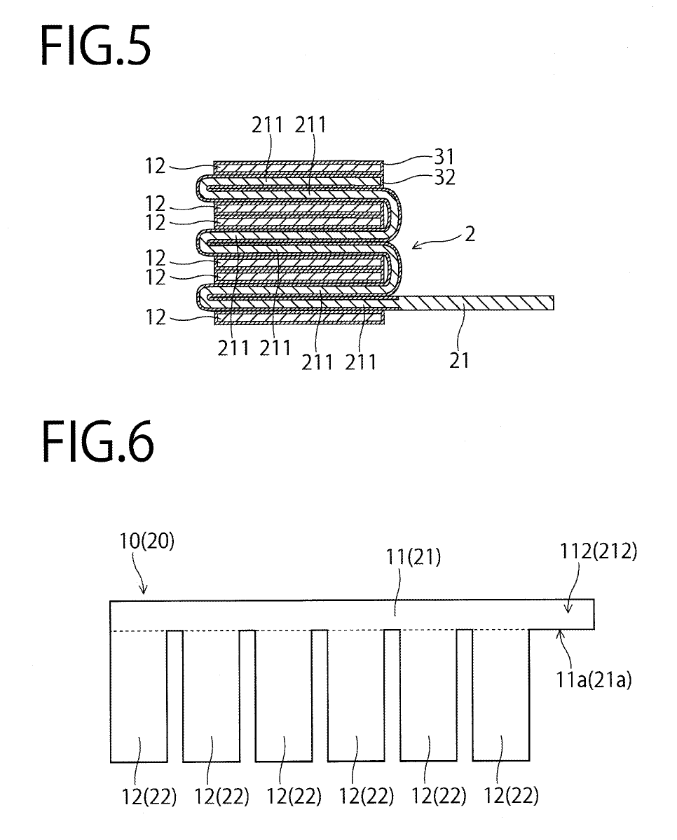

FIG. 2 is a perspective view of the stacked structure 101. FIG. 3 is a sectional view taken along line III-III of FIG. 2. FIG. 4 is a sectional view taken along line IV-IV of FIG. 2. FIG. 5 is a sectional view taken along line V-V of FIG. 2. As shown in FIGS. 2 and 3, the stacked structure 101 includes a first electrode part 1 to form an anode part of an electrode, a second electrode part 2 to form a cathode part of the electrode, and dielectric layers 31 and 32.

Respective electrode members to form the first and second electrode parts 1 and 2 are foils having conductivity. These foils are made of a valve metal such as tantalum (Ta), niobium (Ni), titanium (Ti), aluminum (Al), hafnium (Hf) and zirconium (Zr), or an alloy mainly containing a valve metal. Among these metals, tantalum (Ta), niobium (Ni), and titanium (Ti) are suitable materials as oxides thereof (to become dielectric layers) are in a stable condition even in a high temperature. As an alloy to be used, an alloy made of a combination of two or more types of valve metals is applicable such as a combination of tantalum (Ta) and niobium (Ni). Alternatively, as a material of the foils, metal except a valve metal such as copper (Cu), silver (Ag), gold (Au), platinum (Pt) and an Ag—Pd alloy, or an alloy not containing a valve metal as a main component, is applicable. Meanwhile, in order to form the dielectric layers by anodic oxidation of the electrode members as described below, thin films made of a valve metal or an alloy mainly containing a valve metal should be formed on surfaces of the foils.

The surfaces of the foils may be etched or not. Meanwhile, if etched, the surfaces of the foils are given a plurality of fine projections and recesses to increase the surface areas of the foils. The surfaces of the foils may be given porous layers made of valve metal particles.

The first electrode part 1 includes a first strip portion 11, and a plurality of first plate portions 12 extending from a side edge 11a of the first strip portion 11. In the first embodiment, six first plate portions 12 are provided to the first strip portion 11. The number of the first plate portions 12 is not limited to six.

As shown in FIG. 4, the first strip portion 11 has a bellows shape. The first strip portion 11 includes first flat sections 111 in the same number as that of the first plate portions 12. Each of the first plate portions 12 extends from a corresponding one of the first flat sections 111 (see FIG. 3). The first flat sections 111 arrange in substantially parallel to each other, so that the first plate portions 12 are arranged in substantially parallel to each other.

The second electrode part 2 includes a second strip portion 21, and a plurality of second plate portions 22 extending from a side edge 21a of the second strip portion 21. In the first embodiment, six second plate portions 22 are provided to the second strip portion 21. The number of the second plate portions 22 is not limited to six.

As shown in FIG. 5, the second strip portion 21 has a bellows shape. The second strip portion 21 includes second flat sections 211 in the same number as that of the second plate portions 22. Each of the second plate portions 22 extends from a corresponding one of the second flat sections 211 (see FIG. 3). The second flat sections 211 arrange in substantially parallel to each other, so that the second plate portions 22 are arranged in substantially parallel to each other.

As shown in FIG. 3, the first and second electrode parts 1 and 2 are arranged such that tip ends of the first plate portions 12 and tip ends of the second plate portions 22 point in opposite directions. The first and second electrode parts 1 and 2 are also arranged such that the first plate portions 12 and the second plate portions 22 are stacked in a predetermined order. In the first embodiment, one and another of the first plate portions 12 are placed in the top and bottom layers, and two of the first plate portions 12 and two of the second plate portions 22 are stacked alternately in inner layers (layers except the top and bottom layers).

In the aforementioned arrangement, each of the first plate portions 12 faces a second plate portion 22 stacked on this first plate portion 12 and a second flat section 211 from which this second plate portion 22 extends. Further, each of the second plate portions 22 faces a first plate portion 12 stacked on this second plate portion 22 and a first flat section 111 from which this first plate portion 12 extends.

A surface of each of the first plate portions 12 and a surface of a first flat section 111 from which this first plate portion 12 extends are oxidized to form an oxide coating film thereon as shown in FIGS. 3 to 5. This oxide coating film becomes the dielectric layer 31. Further, a surface of each of the second plate portions 22 and a surface of a second flat section 211 from which this second plate portion 22 extends are oxidized to form an oxide coating film thereon as shown in FIGS. 3 to 5. This oxide coating film becomes the dielectric layer 32. So, the dielectric layers 31 and 32 are placed between the first plate portions 12 and adjacent ones of the second plate portions 22, between the first plate portions 12 and adjacent ones of the second flat sections 211, and between the second plate portions 22 and adjacent ones of the first flat sections 111. The dielectric layer 31 may be a ceramic layer formed on the surfaces of the first plate portions 12 and the first flat sections 111. Further, the dielectric layer 32 may be a ceramic layer formed on the surfaces of the second plate portions 22 and the second flat sections 211. These are not the only structures of the stacked structure of the invention, but the dielectric layer 31 or 32 may be omitted in the stacked structure 101.

Although not shown in the drawings, an intermediate layer may be provided between the dielectric layers 31 and 32 adjacent to each other to connect the dielectric layers 31 and 32 adhesively. An adhesive material used to form this intermediate layer may have either electrically insulating properties or conductivity. Examples of the adhesive material include resin, rubber, and an adhesive agent. If a conductive material is used to form the intermediate layer, the intermediate layer becomes a floating electrode placed between the dielectric layers 31 and 32. This suppresses reduction in electrostatic capacitance due to provision of the intermediate layer.

In the aforementioned stacked capacitor, the first and second strip portions 11 and 21 form anode and cathode collectors respectively. Further, an end section 112 of the first strip portion 11 and an end section 212 of the second strip portion 21 are pulled out of the outer package 102 as shown in FIG. 1, and these end sections 112 and 212 form an anode terminal 103 and a cathode terminal 104 respectively.

A method of manufacturing the stacked capacitor of the first embodiment is described next. This manufacturing method includes an electrode sheet forming step, a dielectric layer forming step, an overlapping step, a folding step, and an outer package forming step that are performed sequentially in this order.

FIG. 6 is a plan view used for explanation of the electrode sheet forming step of the first embodiment. As shown in FIG. 6, in the electrode sheet forming step, a foil having conductivity is die-cut into a predetermined shape to form a first electrode sheet 10 to become the first electrode part 1. The first electrode sheet 10 includes the first strip portion 11, and the plurality of first plate portions 12 extending in the form of comb teeth from the side edge 11a of the first strip portion 11. In the first embodiment, six first plate portions 12 are provided to the first strip portion 11.

In the electrode sheet forming step, a foil having conductivity is further die-cut into a predetermined shape to form a second electrode sheet 20 to become the second electrode part 2 (see FIG. 6). The second electrode sheet 20 includes the second strip portion 21, and the plurality of second plate portions 22 extending in the form of comb teeth from the side edge 21a of the second strip portion 21. In the first embodiment, six second plate portions 22 are provided to the second strip portion 21. The second electrode sheet 20 may be formed in a step difference from the step of forming the first electrode sheet 10.

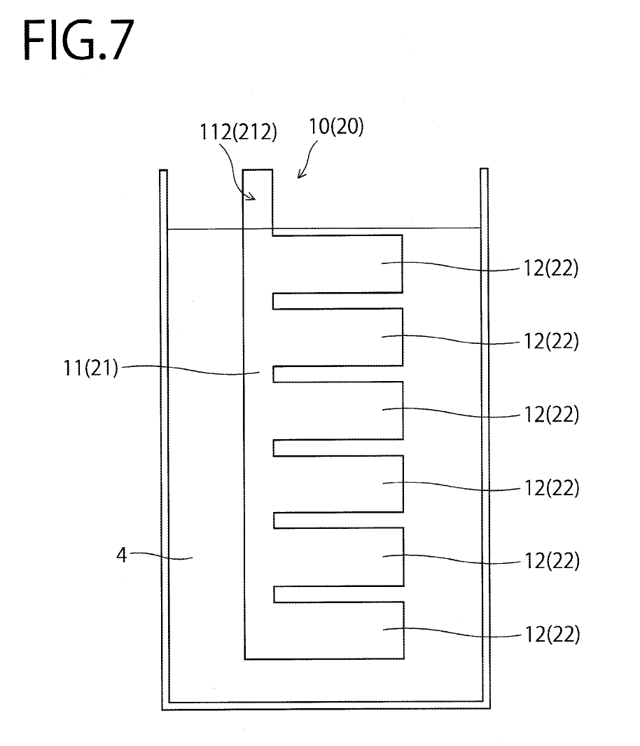

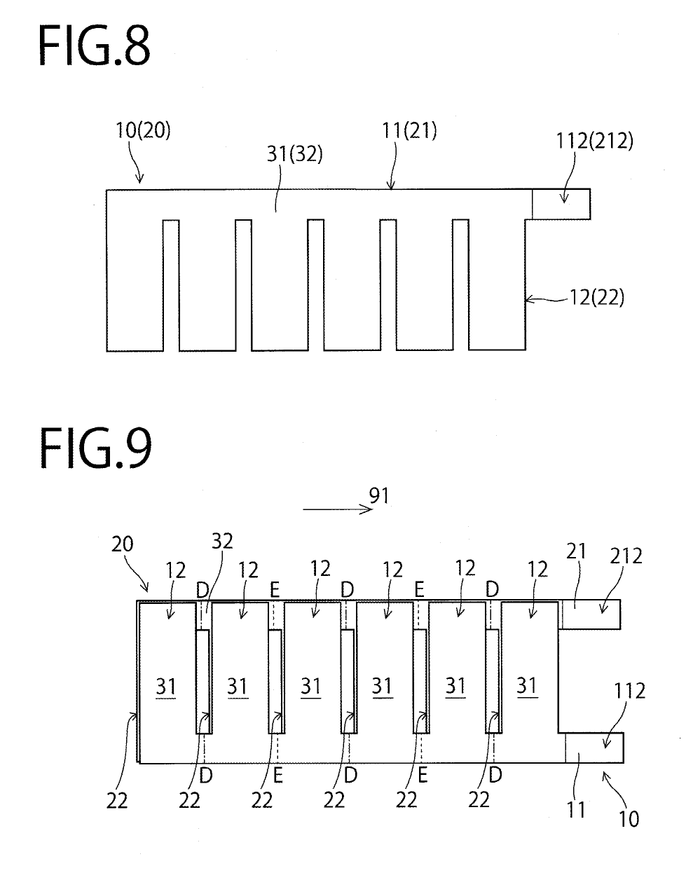

FIG. 7 is a view used for explanation of the dielectric layer forming step of the first embodiment. As shown in FIG. 7, in the dielectric layer forming step, surfaces of the first strip portion 11 and the first plate portions 12 are subjected to chemical conversion process. More specifically, part of the first electrode sheet 10 except the end section 112 of the first strip portion 11 is dipped in a solution 4 for chemical conversion such as an aqueous solution of boron. In this condition, a voltage is applied between the first electrode sheet 10 and the solution 4 for chemical conversion to electrochemically oxidize a surface of the first electrode sheet 10 (anodic oxidation). As a result, an oxide coating film is formed on the surfaces of the first strip portion 11 and the first plate portions 12, and the oxide coating film thereby formed becomes the dielectric layer 31 as shown in FIG. 8. Instead of the oxide coating film, a ceramic layer may be formed as the dielectric layer 31 on the surfaces of the first strip portion 11 and the first plate portions 12.

In the dielectric layer forming step, surfaces of the second strip portion 21 and the second plate portions 22 are further subjected to chemical conversion process in the same manner as that of the aforementioned chemical conversion process (see FIG. 7). As a result, an oxide coating film is formed on the surfaces of the second strip portion 21 and the second plate portions 22, and the oxide coating film thereby formed becomes the dielectric layer 32 (see FIG. 8). Instead of the oxide coating film, a ceramic layer may be formed as the dielectric layer 32 on the surfaces of the second strip portion 21 and the second plate portions 22. The dielectric layer 32 may be formed in a step difference from the step of forming the dielectric layer 31.

FIG. 9 is a plan view used for explanation of the overlapping step of the first embodiment. As shown in FIG. 9, in the overlapping step, the first and second electrode sheets 10 and 20 are made to overlap each other such that tip ends of the first plate portions 12 and tip ends of the second plate portions 22 point in opposite directions. At this time, the second electrode sheet 20 is arranged with respect to the first electrode sheet 10 such that the second plate portions 22 overlap the first plate portions 12 one by one from the same direction, and that regarding each of the first plate portions 12 and a second plate portion 22 to overlap this first plate portion 12, a tip end of this first plate portion 12 overlaps the second strip portion 21 and a tip end of this second plate portion 22 overlaps the first strip portion 11.

Although not shown in the drawings, an adhesive material to become an intermediate layer may be applied on surfaces of the dielectric layers 31 and 32 before the overlapping step is performed. The adhesive material can be applied by various processes including spin-coating process, dipping process, drop casting process, ink jet process, spraying process, screen printing process, gravure printing process, flexographic process, and deposition process.

In the folding step, the first and second strip portions 11 and 21 are folded together in a bellows shape (see FIG. 2). More specifically, the first and second strip portions 11 and 21 are mountain folded together at three positions along lines D (dashed-dotted lines) shown in FIG. 9, and are valley folded together at two positions along lines E (dashed lines) shown in FIG. 9. Thus, first plate portions 12 adjacent to each other in a longitudinal direction 91 are placed one above the other in facing positions, and second plate portions 22 adjacent to each other in the longitudinal direction 91 are placed one above the other in facing positions, thereby completing the formation of the stacked structure 101 shown in FIG. 2.

In the outer package forming step, the stacked structure 101 is sealed under vacuum with a laminated film as shown in FIG. 1. At this time, the end section 112 of the first strip portion 11 and the end section 212 of the second strip portion 21 are not covered with the laminated film but they are pulled out of the laminated film. Then, the outer package 102 is formed to complete the formation of the stacked capacitor shown in FIG. 1. The outer package 102 may be molded with an electrically insulating material such as an epoxy resin to cover the stacked structure 101. If the outer package 102 is made unnecessary depending on a stacked capacitor to be formed, the outer package forming step is not performed.

In the manufacturing method of the first embodiment, the first plate portions 12 and the first strip portion 11 are together treated as one sheet, and the second plate portions 22 and the second strip portion 21 are together treated as one sheet. More specifically, the first and second strip portions 11 and 21 are folded to change the shapes thereof, so that the first plate portions 12 and the second plate portions 22 are arranged at positions according to the shapes of the first and second strip portions 11 and 21 respectively. So, the first embodiment avoids complicated process of handling the first plate portions 12 and the second plate portions 22 individually. This shortens time required for stacking the first plate portions 12 and the second plate portions 22, thereby increasing manufacturing efficiency of the stacked capacitor.

In the dielectric layer forming step, the dielectric layer 31 is formed on the surfaces of the first plate portions 12 and the first strip portion 11, and the dielectric layer 32 is formed on the surfaces of the second plate portions 22 and the second strip portion 21. Further, in the overlapping step, regarding each of the first plate portions 12 and a second plate portion 22 to overlap this first plate portion 12, the tip end of this first plate portion 12 overlaps the second strip portion 21 and the tip end of this second plate portion 22 overlaps the first strip portion 11. So, in the stacked capacitor thereby formed, the first and second strip portions 11 and 21 function as anode and cathode collectors respectively and further as parts of electrodes each of which forms a capacitor element. So, a facing area of each of electrode pairs in which the electrodes in this pair face each other, becomes larger to increase an electrostatic capacitance per unit volume.

### 2. Second Embodiment

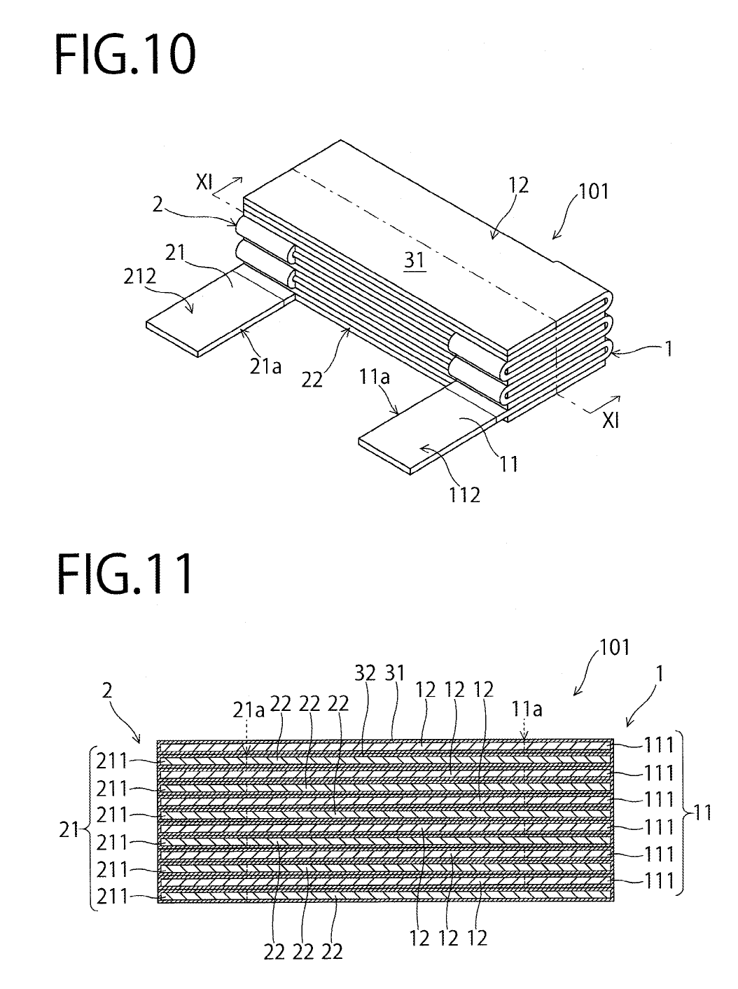

FIG. 10 is a perspective view of a stacked structure 101 of a stacked capacitor of a second embodiment. FIG. 11 is a sectional view taken along line XI-XI of FIG. 10. Regarding the structure of the stacked capacitor of the second embodiment, a difference from the structure of the first embodiment is described below. The same structure as that of the first embodiment will not be described again.

As shown in FIGS. 10 and 11, first and second electrode parts 1 and 2 are arranged such that first plate portions 12 and second plate portions 22 are stacked one by one alternately. In this arrangement, a tip end of each of the second plate portions 22 is placed between corresponding two first flat sections 111 adjacent to each other but a first strip portion 11 is not placed therebetween. Further, a tip end of each of the first plate portions 12 is placed between corresponding two second flat sections 211 adjacent to each other but a second strip portion 21 is not placed therebetween.

A method of manufacturing the stacked capacitor of the second embodiment is described next. This manufacturing method includes an electrode sheet forming step, a dielectric layer forming step, an overlapping step, a folding step, and an outer package forming step that are performed sequentially in this order. The electrode sheet forming step, the dielectric layer forming step, and the outer package forming step are the same as those of the first embodiment, so they will not be described again.

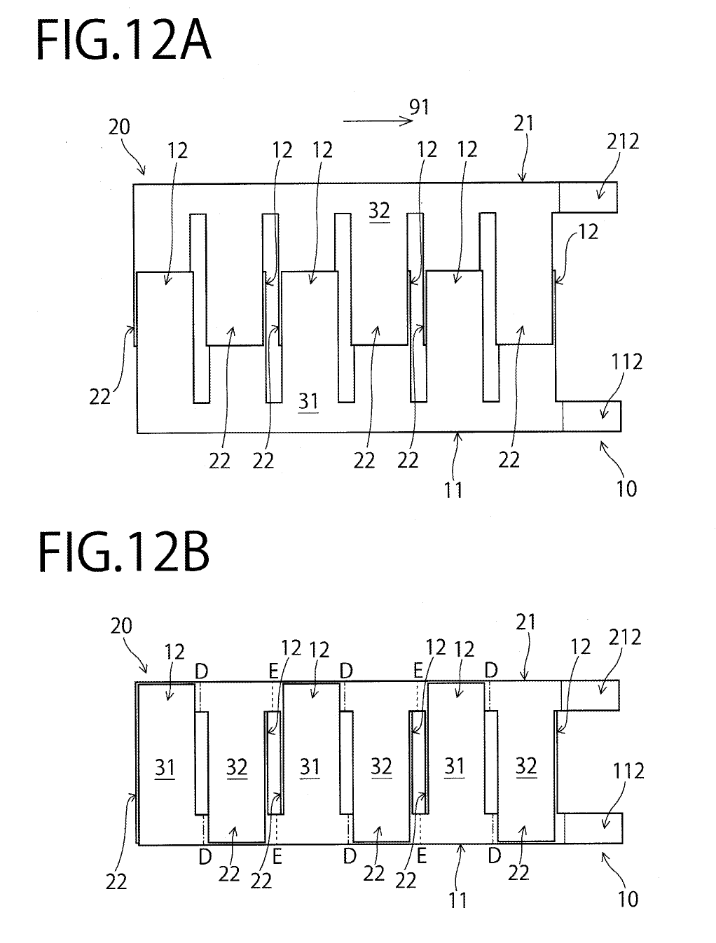

FIGS. 12A and 12B are plan views used for explanation of the overlapping step of the second embodiment. As shown in FIG. 12A, in the overlapping step, first and second electrode sheets 10 and 20 are first made to overlap each other such that tip ends of the first plate portions 12 and tip ends of the second plate portions 22 point in opposite directions. At this time, the second electrode sheet 20 is arranged with respect to the first electrode sheet 10 such that the second plate portions 22 overlap the first plate portions 12 one by one, and that upper and lower positions of the first plate portions 12 and the second plate portions 22 with respect to each other (forward and backward positions with respect to each other in the plane of FIG. 12A) are changed alternately in a longitudinal direction 91 of the first or second strip portion 11 or 12. Like in the first embodiment, an adhesive material to become an intermediate layer may be applied on surfaces of dielectric layers 31 and 32 before the overlapping step is performed.

Next, as shown in FIG. 12B, the first and second strip portions 11 and 21 are made to get closer to each other to place tip end sections of the first plate portions 12 on the second strip portion 21 and to place tip end sections of the second plate portions 22 on the first strip portion 11.

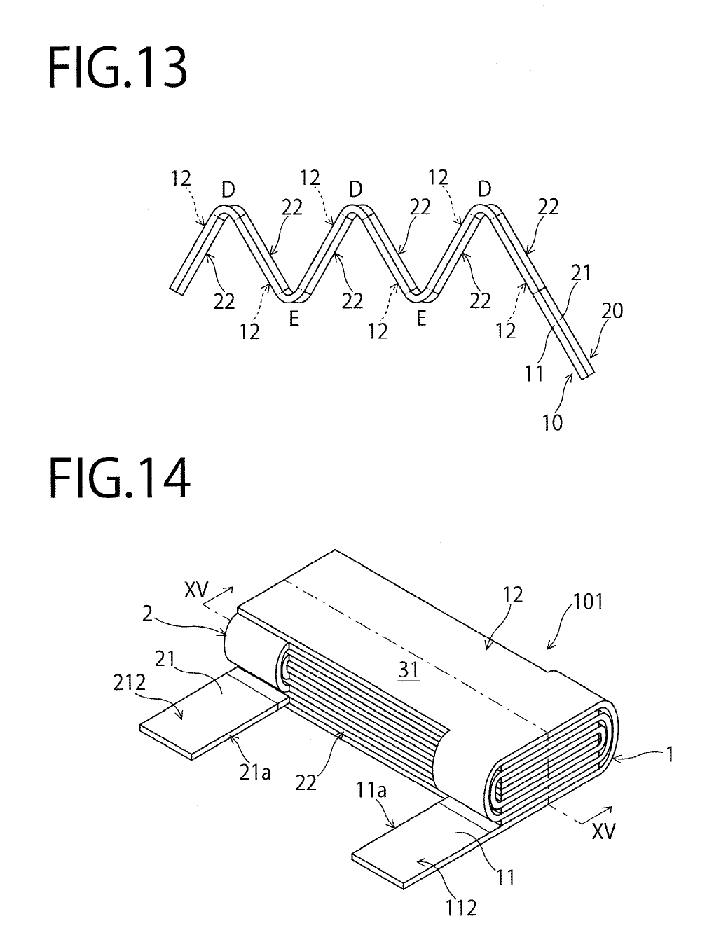

FIG. 13 is a side view used for explanation of the folding step of the second embodiment. As shown in FIG. 13, in the folding step, the first and second strip portions 11 and 21 are folded together in a bellows shape. More specifically, the first and second strip portions 11 and 21 are mountain folded together at three positions along lines D (dashed-dotted lines) shown in FIG. 12B, and are valley folded together at two positions along lines E (dashed lines) shown in FIG. 12B. Thus, each of the first plate portions 12 and a corresponding one of the second plate portions 22 which have been adjacent to each other in the longitudinal direction 91, are placed one above the other in facing positions, thereby completing the formation of the stacked structure 101 shown in FIG. 10.

The stacked capacitor formed by the manufacturing method of the second embodiment has a structure where the first plate portions 12 and the second plate portions 22 are stacked one by one alternately. So, the stacked capacitor is given electrode pairs in number substantially the same as a total of the number of the first plate portions 12 and that of the second plate portions 22. Thus, compared to the stacked capacitor of the first embodiment, this increases a total of the facing areas of the electrode pairs, so that an electrostatic capacitance per unit volume is increased significantly.

Further, the upper and lower positions of the first plate portions 12 and the second plate portions 22 with respect to each other are changed alternately in the overlapping step. Thus, in the folding step, the first plate portions 12 and the second plate portions 22 can be stacked one by one alternately without involving increase in the number of times the first and second strip portions 11 and 21 are folded to have a bellows shape (by folding the first and second strip portions 11 and 21 the same number of times as that of the first embodiment). Thus, high manufacturing efficiency is achieved as in the first embodiment.

### 3. Third Embodiment

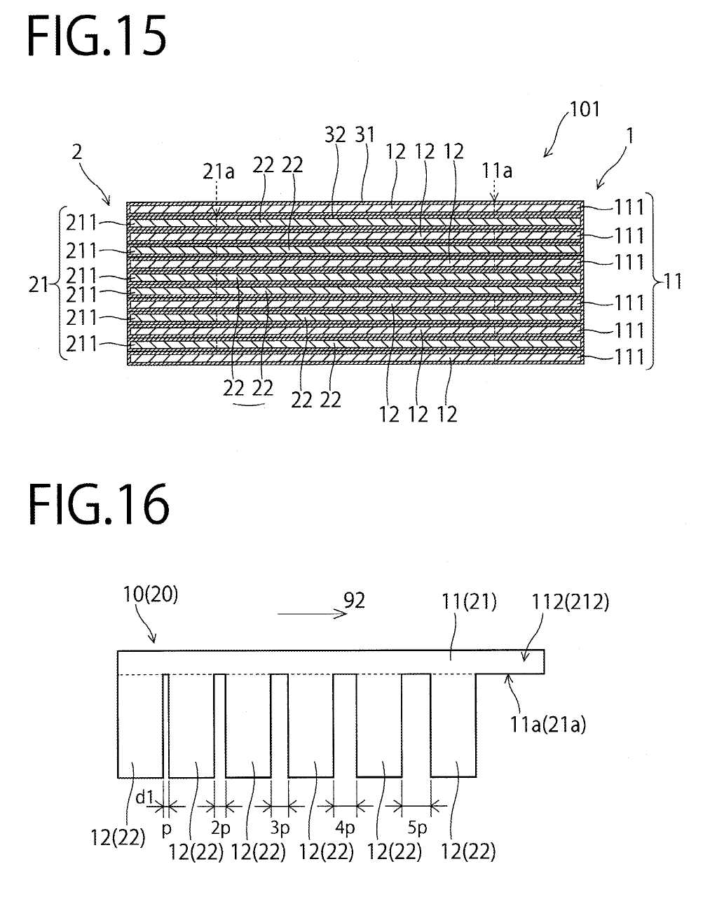

FIG. 14 is a perspective view of a stacked structure 101 of a stacked capacitor of a third embodiment. FIG. 15 is a sectional view taken along line XV-XV of FIG. 14. Regarding the structure of the stacked capacitor of the third embodiment, a difference from the structure of the first embodiment is described below. The same structure as that of the first embodiment will not be described again.

As shown in FIG. 14, a first strip portion 11 has a spiral shape. The first strip portion 11 includes first flat sections 111 in the same number as that of first plate portions 12. Each of the first plate portions 12 extends from a corresponding one of the first flat sections 111 (see FIG. 15). The first flat sections 111 arrange in substantially parallel to each other, so that the first plate portions 12 are arranged in substantially parallel to each other.

Further, a second strip portion 21 has a spiral shape. The second strip portion 21 includes second flat sections 211 in the same number as that of second plate portions 22. Each of the second plate portions 22 extends from a corresponding one of the second flat sections 211 (see FIG. 15). The second flat sections 211 arrange in substantially parallel to each other, so that the second plate portions 22 are arranged in substantially parallel to each other.

As shown in FIG. 15, first and second electrode parts 1 and 2 are arranged such that the first plate portions 12 and the second plate portions 22 are stacked in a predetermined order. In the third embodiment, two of the second plate portions 22 overlap each other, and the first plate portions 12 and the other second plate portions 22 are placed one by one alternately in upper layers and lower layers with respect to the two overlapping second plate portions 22.

In the aforementioned arrangement, each of the first plate portions 12 faces a second plate portion 22 stacked on this first plate portion 12 and a second flat section 211 from which this second plate portion 22 extends. Further, each of the second plate portions 22 faces a first plate portion 12 stacked on this second plate portion 22 and a first flat section 111 from which this first plate portion 12 extends.

A method of manufacturing the stacked capacitor of the third embodiment is described next. This manufacturing method includes an electrode sheet forming step, a dielectric layer forming step, an overlapping step, a folding step, and an outer package forming step that are performed sequentially in this order. The outer package forming step is the same as that of the first embodiment, so it will not be described again.

FIG. 16 is a plan view used for explanation of the electrode sheet forming step of the third embodiment. As shown in FIG. 16, in the electrode sheet forming step, a foil having conductivity is die-cut into a predetermined shape to form a first electrode sheet 10 to become the first electrode part 1. At this time, a distance d1 between two of the first plate portions 12 adjacent to each other is set to become greater gradually with progress in a longitudinal direction 92 of the first strip portion 11.

In the third embodiment, six first plate portions 12 are provided to the first strip portion 11. Based on a value p of the distance d1 between two of the first plate portions 12 close to the left edge of the first strip portion 11 in the plane of FIG. 16, the distance d1 is set to become greater gradually with progress in the longitudinal direction 92; it becomes about twice, about three times, about four times, and about five times the value p. The second electrode sheet 20 has a shape substantially the same as that of the first electrode sheet 10. This is not the only way of setting the distance d1, but the distance d1 can be set in various different ways.

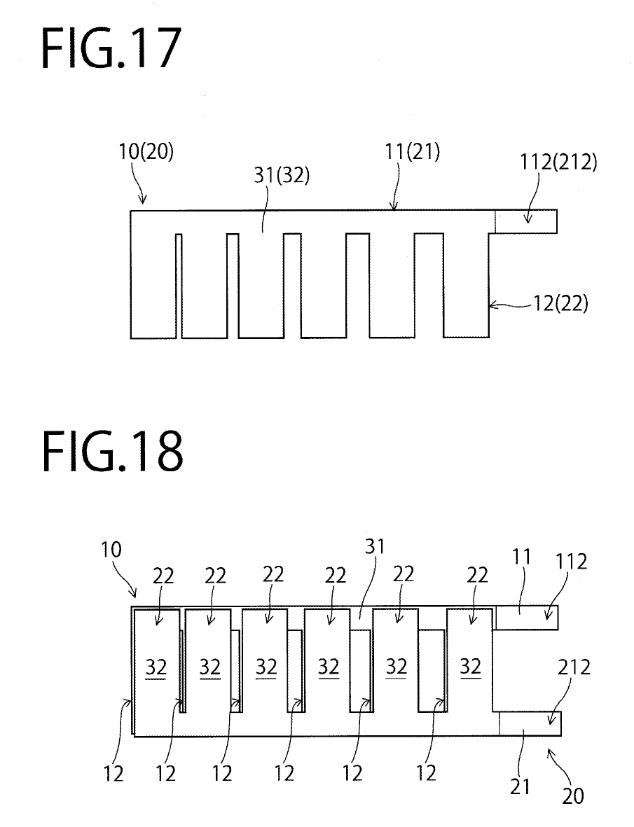

FIG. 17 is a plan view used for explanation of the dielectric layer forming step of the third embodiment. Like in the first embodiment, surfaces of the first strip portion 11 and the first plate portions 12 are subjected to chemical conversion process, and surfaces of the second strip portion 21 and the second plate portions 22 are subjected to chemical conversion process in the dielectric layer forming step (see FIG. 7). As a result, an oxide coating film is formed on the surfaces of the first strip portion 11 and the first plate portions 12, and the oxide coating film thereby formed becomes a dielectric layer 31 as shown in FIG. 17. Further, an oxide coating film is formed on the surfaces of the second strip portion 21 and the second plate portions 22, and the oxide coating film thereby formed becomes a dielectric layer 32 as shown in FIG. 17.

FIG. 18 is a plan view used for explanation of the overlapping step of the third embodiment. As shown in FIG. 18, in the overlapping step, the first and second electrode sheets 10 and 20 are made to overlap each other such that tip ends of the first plate portions 12 and tip ends of the second plate portions 22 point in opposite directions. At this time, the second electrode sheet 20 is arranged with respect to the first electrode sheet 10 such that the second plate portions 22 overlap the first plate portions 12 one by one from the same direction, and that regarding each of the first plate portions 12 and a second plate portion 22 to overlap this first plate portion 12, a tip end of this first plate portion 12 overlaps the second strip portion 21 and a tip end of this second plate portion 22 overlaps the first strip portion 11. Like in the first embodiment, an adhesive material to become an intermediate layer may be applied on surfaces of the dielectric layers 31 and 32 before the overlapping step is performed.

In the folding step, the first and second strip portions 11 and 21 are folded together in a spiral shape (see FIG. 14). More specifically, the first and second strip portions 11 and 21 are wound from their left edges in the plane of FIG. 18. So, adjacent second plate portions 22 are placed one above the other in facing positions in the first folding. In each subsequent folding, a first plate portion 12 at the left edge is placed on an adjacent one of the second plate portions 22, thereby completing the formation of the stacked structure 101 shown in FIG. 14.

In the first electrode sheet 10, the distance d1 between two of the first plate portions 12 adjacent to each other is set to become greater gradually with progress in the longitudinal direction 92 of the first strip portion 11 (see FIG. 16). Additionally, the second electrode sheet 20 has a shape substantially the same as that of the first electrode sheet 10. Thus, the first and second strip portions 11 and 21 are folded (wound) easily in the folding step.

In the manufacturing method of the third embodiment, the first plate portions 12 and the first strip portion 11 are together treated as one sheet, and the second plate portions 22 and the second strip portion 21 are together treated as one sheet. So, like the first embodiment, the third embodiment avoids complicated process of handling the first plate portions 12 and the second plate portions 22 individually. This shortens time required for stacking the first plate portions 12 and the second plate portions 22, thereby increasing manufacturing efficiency the stacked capacitor.

Like in the first embodiment, in the stacked capacitor to be formed, the first and second strip portions 11 and 21 function as anode and cathode collectors respectively and further as parts of electrodes each of which forms a capacitor element. So, the facing areas of electrode pairs become larger to increase an electrostatic capacitance per unit volume.

### 4. Fourth Embodiment

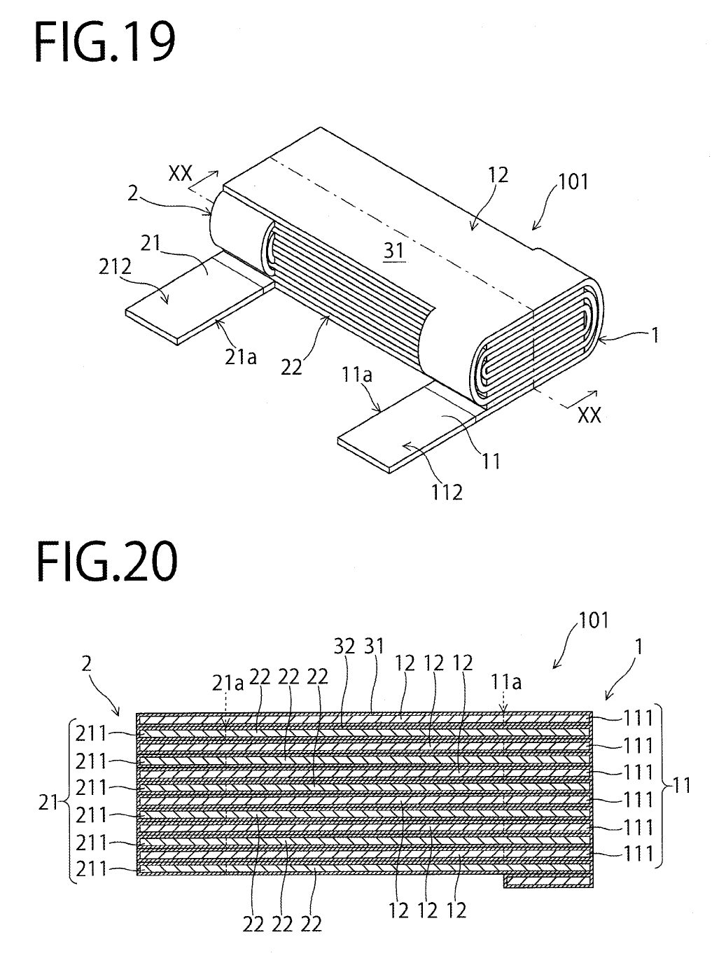

FIG. 19 is a perspective view of a stacked structure 101 of a stacked capacitor of a fourth embodiment. FIG. 20 is a sectional view taken along line XX-XX of FIG. 19. Regarding the structure of the stacked capacitor of the fourth embodiment, a difference from the structure of the third embodiment is described below. The same structure as that of the third embodiment will not be described again.

As shown in FIGS. 19 and 20, first and second electrode parts 1 and 2 are arranged such that first plate portions 12 and second plate portions 22 are stacked one by one alternately. In this arrangement, a tip end of each of the second plate portions 22 is placed between corresponding two first flat sections 111 adjacent to each other but a first strip portion 11 is not placed therebetween. Further, a tip end of each of the first plate portions 12 is placed between corresponding two second flat sections 211 adjacent to each other but a second strip portion 21 is not placed therebetween.

A method of manufacturing the stacked capacitor of the fourth embodiment is described next. This manufacturing method includes an electrode sheet forming step, a dielectric layer forming step, an overlapping step, a folding step, and an outer package forming step that are performed sequentially in this order. The outer package forming step is the same as that of the first embodiment, so it will not be described again.

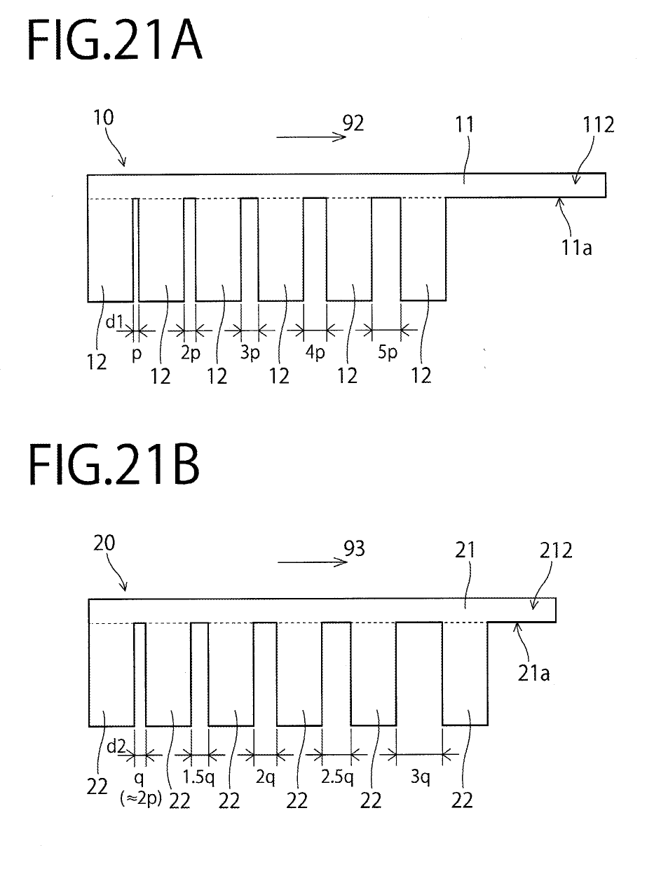

FIGS. 21A and 21B are plan views used for explanation of the electrode sheet forming step of the fourth embodiment. As shown in FIG. 21A, in the electrode sheet forming step, a foil having conductivity is die-cut into a predetermined shape to form a first electrode sheet 10 to become the first electrode part 1. At this time, a distance d1 between two of the first plate portions 12 adjacent to each other is set to become greater gradually with progress in a longitudinal direction 92 of the first strip portion 11.

In the fourth embodiment, six first plate portions 12 are provided to the first strip portion 11. Based on a value p of the distance d1 between two of the first plate portions 12 close to the left edge of the first strip portion 11 in the plane of FIG. 21A, the distance d1 is set to become greater gradually with progress in the longitudinal direction 92; it becomes about twice, about three times, about four times, and about five times the value p. This is not the only way of setting the distance d1, but the distance d1 can be set in various different ways.

As shown in FIG. 21B, in the electrode sheet forming step, a foil having conductivity is further die-cut into a predetermined shape to form a second electrode sheet 20 to become the second electrode part 2. At this time, a distance d2 between two of the second plate portions 22 adjacent to each other is set to become greater gradually with progress in a longitudinal direction 93 of the second strip portion 21.

In the fourth embodiment, six second plate portions 22 are provided to the second strip portion 21. Based on a value q of the distance d2 between two of the second plate portions 22 close to the left edge of the second strip portion 21 in the plane of FIG. 21B, the distance d2 is set to become greater gradually with progress in the longitudinal direction 93; it becomes about 1.5 times, about twice, about 2.5 times, and about three times the value q. The value q is set about twice the value p. This is not the only way of setting the distance d2, but the distance d2 can be set in various different ways.

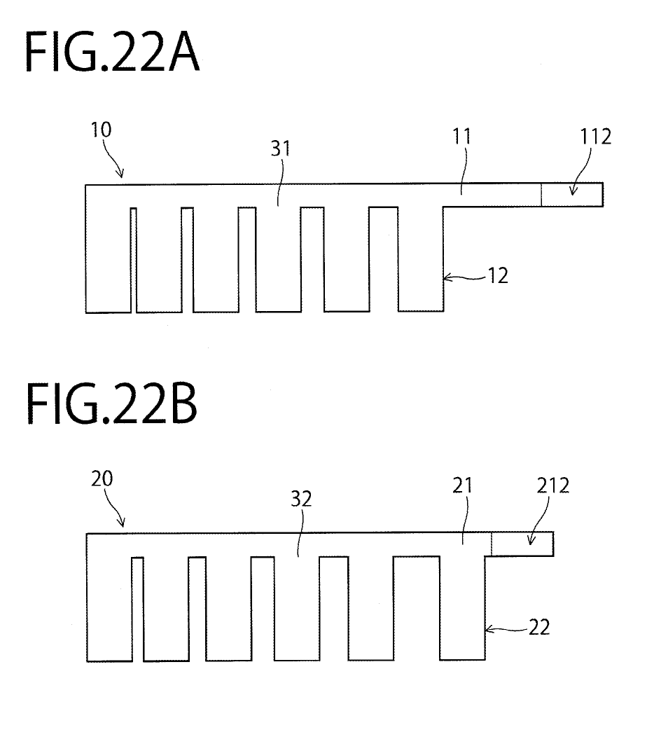

FIGS. 22A and 22B are plan views used for explanation of the dielectric layer forming step of the fourth embodiment. Like in the first embodiment, surfaces of the first strip portion 11 and the first plate portions 12 are subjected to chemical conversion process, and surfaces of the second strip portion 21 and the second plate portions 22 are subjected to chemical conversion process in the dielectric layer forming step (see FIG. 7). As a result, an oxide coating film is formed on the surfaces of the first strip portion 11 and the first plate portions 12, and the oxide coating film thereby formed becomes a dielectric layer 31 as shown in FIG. 22A. Further, an oxide coating film is formed on the surfaces of the second strip portion 21 and the second plate portions 22, and the oxide coating film thereby formed becomes a dielectric layer 32 as shown in FIG. 22B.

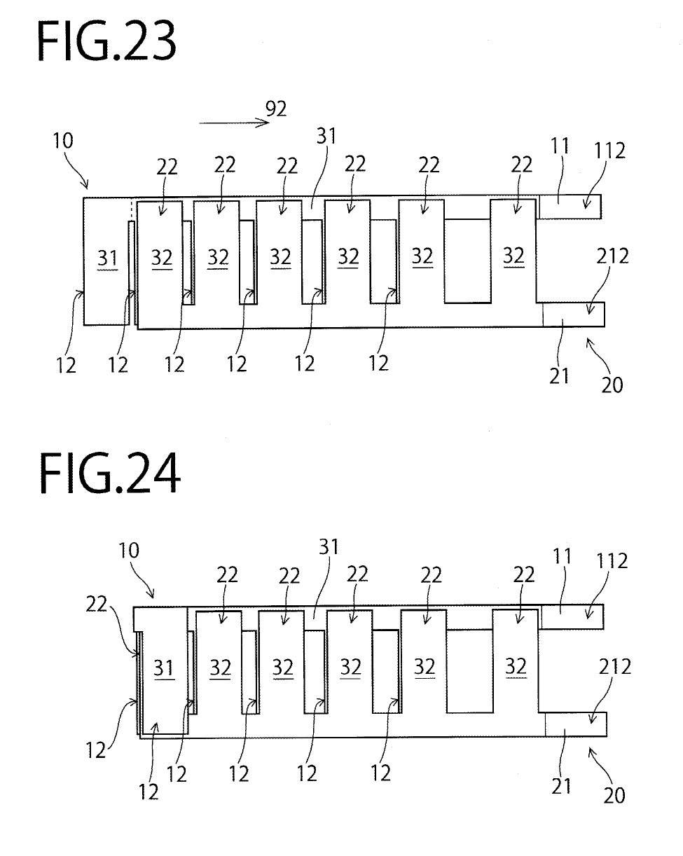

FIG. 23 is a plan view used for explanation of the overlapping step of the fourth embodiment. As shown in FIG. 23, in the overlapping step, the first and second electrode sheets 10 and 20 are made to overlap each other such that tip ends of the first plate portions 12 and tip ends of the second plate portions 22 point in opposite directions. At this time, the second electrode sheet 20 is arranged with respect to the first electrode sheet 10 such that none of the second plate portions 22 overlaps one of the first plate portions 12 closest to one edge of the first strip portion 11 in the longitudinal direction 92 (left edge of the first strip portion 11 in the plane of FIG. 23), and that the second plate portions 22 overlap the other first plate portions 12 one by one. Like in the first embodiment, an adhesive material to become an intermediate layer may be applied on surfaces of the dielectric layers 31 and 32 before the overlapping step is performed.

FIG. 24 is a plan view used for explanation of the folding step of the fourth embodiment. As shown in FIG. 24, in the folding step, the first and second strip portions 11 and 21 are folded (wound) together in a spiral shape. At this time, the first plate portion 12 with no second plate portion 22 thereon is first placed on an adjacent one of the second plate portions 22, and then the first plate portions 12 are successively placed on adjacent ones of the second plate portions 22, thereby completing the formation of the stacked structure 101 shown in FIG. 19.

In the first electrode sheet 10, the distance d1 between two of the first plate portions 12 adjacent to each other is set to become greater gradually with progress in the longitudinal direction 92 of the first strip portion 11 (see FIG. 21A). Further, in the second electrode sheet 20, the distance d2 between two of the second plate portions 22 adjacent to each other is set to become greater gradually with progress in the longitudinal direction 93 of the second strip portion 21 (see FIG. 21B). Thus, the first and second strip portions 11 and 21 are folded (wound) easily in the folding step.

The stacked capacitor formed by the manufacturing method of the fourth embodiment has a structure where the first plate portions 12 and the second plate portions 22 are stacked one by one alternately. So, the stacked capacitor is given electrode pairs in number substantially the same as a total of the number of the first plate portions 12 and that of the second plate portions 22. Thus, compared to the stacked capacitor of the third embodiment, this increases a total of the facing areas of the electrode pairs, so that an electrostatic capacitance per unit volume is increased significantly.

As a result of provision of the first plate portion 12 with no second plate portion 22 thereon in the overlapping step, the first plate portions 12 and the second plate portions 22 can be stacked one by one alternately in the folding step by simple technique of winding the first and second strip portions 11 and 21. Thus, high manufacturing efficiency is achieved as in the third embodiment.

### 5. Fifth Embodiment

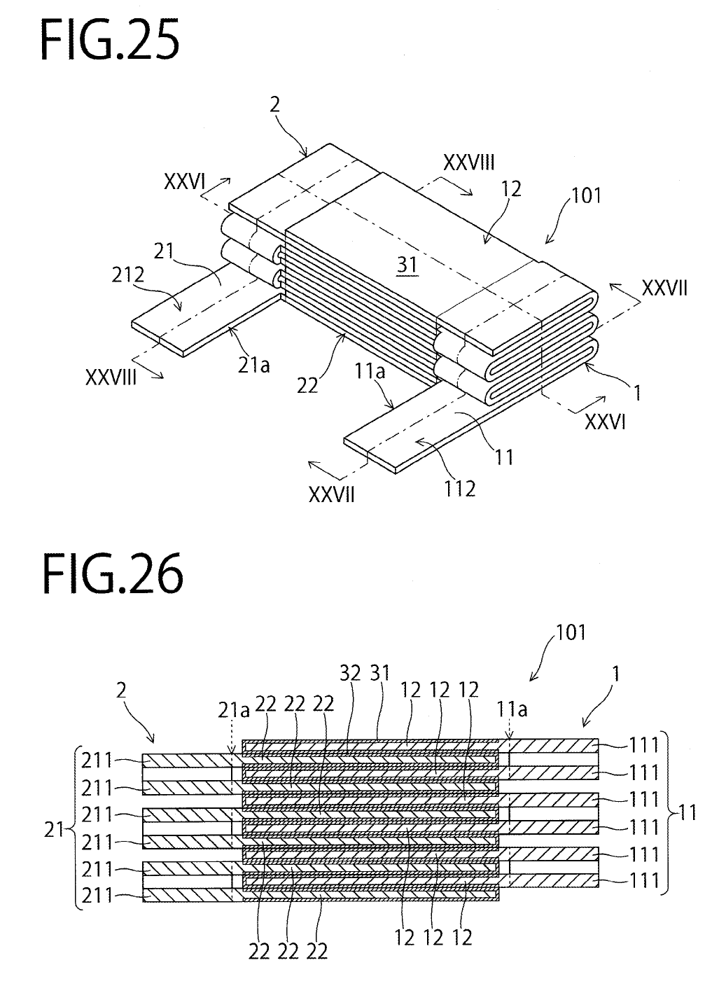

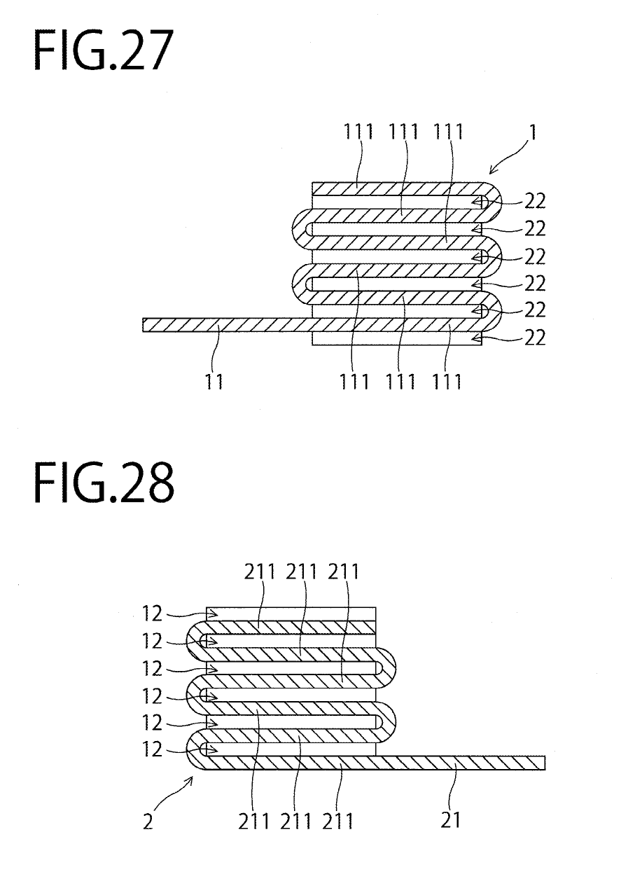

FIG. 25 is a perspective view of a stacked structure 101 of a stacked capacitor of a fifth embodiment. FIG. 26 is a sectional view taken along line XXVI-XXVI of FIG. 25. FIG. 27 is a sectional view taken along line XXVII-XXVII of FIG. 25. FIG. 28 is a sectional view taken along line XXVIII-XXVIII of FIG. 25. Regarding the structure of the stacked capacitor of the fifth embodiment, a difference from the structure of the second embodiment is described below. The same structure as that of the second embodiment will not be described again.

As shown in FIGS. 25 to 28, in the stacked structure 101 of the fifth embodiment, each of the second plate portions 22 is placed between corresponding two first plate portions 12 adjacent to each other but it is not placed between any two first flat sections 111 adjacent to each other. Further, each of the first plate portions 12 is placed between corresponding two second plate portions 22 adjacent to each other but it is not placed between any two second flat sections 211 adjacent to each other. To be specific, the first plate portions 12 face the second plate portions 22 but they do not face the second flat sections 211. Further, the second plate portions 22 face the first plate portions 12 but they do not face the first flat sections 111.

As shown in FIG. 26, in the fifth embodiment, a dielectric layer 31 is formed on surfaces of the first plate portions 12 but it is not formed on a first strip portion 11. Further, a dielectric layer 32 is formed on surfaces of the second plate portions 22 but it is not formed on a second strip portion 21.

A method of manufacturing the stacked capacitor of the fifth embodiment is described next. This manufacturing method includes an electrode sheet forming step, a dielectric layer forming step, an overlapping step, a folding step, and an outer package forming step that are performed sequentially in this order. The electrode sheet forming step, the folding step, and the outer package forming step are the same as those of the second embodiment, so they will not be described again.

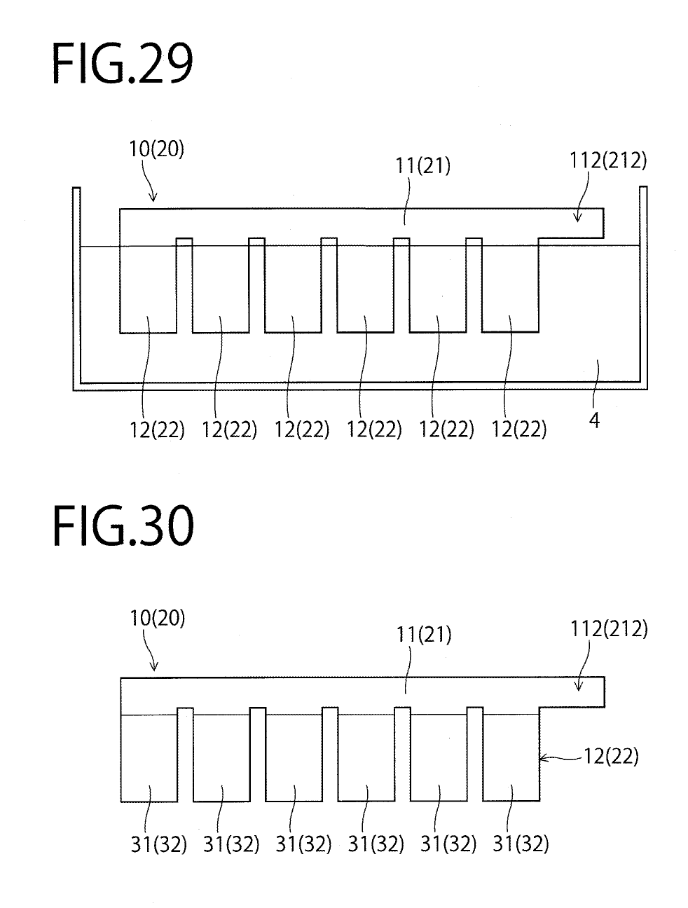

FIG. 29 is a view used for explanation of the dielectric layer forming step of the fifth embodiment. As shown in FIG. 29, in the dielectric layer forming step, surfaces of the first plate portions 12 are subjected to chemical conversion process, whereas the first strip portion 11 is not subjected to chemical conversion process. As a result, an oxide coating film is formed on the surfaces of the first plate portions 12, and the oxide coating film thereby formed becomes the dielectric layer 31 as shown in FIG. 30.

In the dielectric layer forming step, surfaces of the second plate portions 22 are further subjected to chemical conversion process (see FIG. 29), whereas the second strip portion 21 is not subjected to chemical conversion process. As a result, an oxide coating film is formed on the surfaces of the second plate portions 22, and the oxide coating film thereby formed becomes the dielectric layer 32 (see FIG. 30).

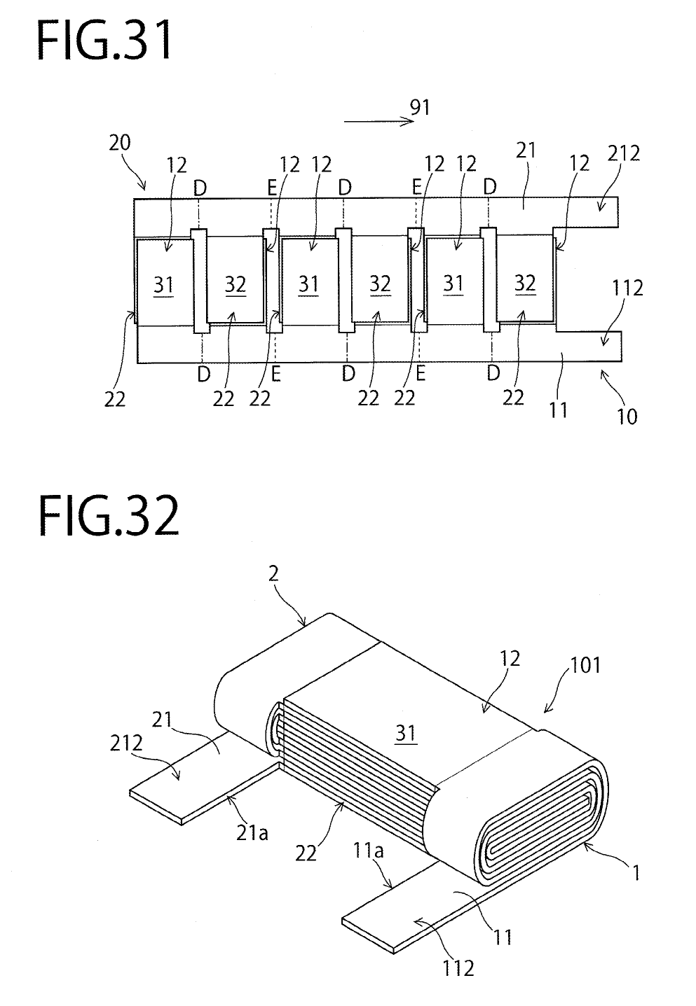

FIG. 31 is a plan view used for explanation of the overlapping step of the fifth embodiment. As shown in FIG. 31, in the overlapping step, first and second electrode sheets 10 and 20 are made to overlap each other such that tip ends of the first plate portions 12 and tip ends of the second plate portions 22 point in opposite directions. At this time, the second electrode sheet 20 is arranged with respect to the first electrode sheet 10 such that the second plate portions 22 overlap the first plate portions 12 one by one, and that upper and lower positions of the first plate portions 12 and the second plate portions 22 with respect to each other (forward and backward positions with respect to each other in the plane of FIG. 31) are changed alternately in a longitudinal direction 91 of the first or second strip portion 11 or 12. In the overlapping step of the fifth embodiment, the first and second strip portions 11 and 21 are not made to get closer to each other. Thus, tip end sections of the first plate portions 12 do not overlap the second strip portion 21 and further, tip end sections of the second plate portions 22 do not overlap the first strip portion 11.

Next, the folding step same as that of the second embodiment is preformed to complete the formation of the stacked structure 101 shown in FIG. 25.

Like the first and second embodiments, the fifth embodiment avoids complicated process of handling the first plate portions 12 and the second plate portions 22 individually. Further, the upper and lower positions of the first plate portions 12 and the second plate portions 22 with respect to each other are changed alternately in the overlapping step. Thus, in the folding step, the first plate portions 12 and the second plate portions 22 can be stacked one by one alternately without involving increase in the number of times the first and second strip portions 11 and 21 are folded to have a bellows shape.

Thus, time required for stacking the first plate portions 12 and the second plate portions 22 is shortened, thereby increasing manufacturing efficiency of the stacked capacitor. Further, the stacked capacitor thereby formed has a structure where the first plate portions 12 and the second plate portions 22 are stacked one by one alternately. In this structure, the first strip portion 11 is not placed between any two of the first flat sections 111 adjacent to each other, and the second strip portion 21 is not placed between any two of the second flat sections 211 adjacent to each other. This avoids volume increase of part not contributing to increase in electrostatic capacitance, so that reduction in electrostatic capacitance per unit volume is avoided.

### 6. Sixth Embodiment

FIG. 32 is a perspective view of a stacked structure 101 of a stacked capacitor of a sixth embodiment. As shown in FIG. 32, in the stacked capacitor of the sixth embodiment, first and second strip portions 11 and 21 each have a spiral shape. The structure of the stacked capacitor of the sixth embodiment is the same in other respects as that of the fifth embodiment, so it will not be described again.

A method of manufacturing the stacked capacitor of the sixth embodiment is described next. This manufacturing method includes an electrode sheet forming step, a dielectric layer forming step, an overlapping step, a folding step, and an outer package forming step that are performed sequentially in this order. The electrode sheet forming step, the folding step, and the outer package forming step are the same as those of the fourth embodiment, so they will not be described again.

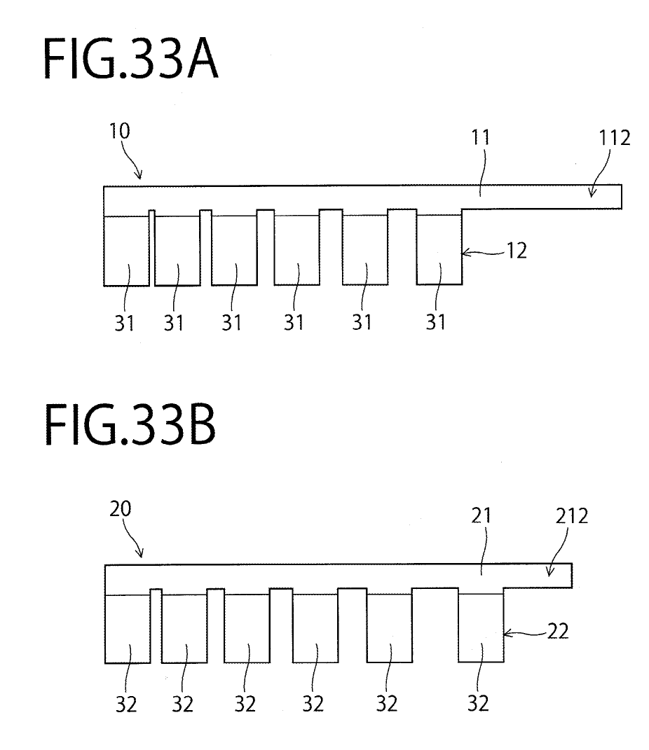

FIGS. 33A and 33B are plan views used for explanation of the dielectric layer forming step of the sixth embodiment. In the dielectric layer forming step, surfaces of first plate portions 12 are subjected to chemical conversion process (see FIG. 29), whereas the first strip portion 11 is not subjected to chemical conversion process. As a result, an oxide coating film is formed on the surfaces of the first plate portions 12, and the oxide coating film thereby formed becomes a dielectric layer 31 as shown in FIG. 33A.

In the dielectric layer forming step, surfaces of second plate portions 22 are further subjected to chemical conversion process (see FIG. 29), whereas the second strip portion 21 is not subjected to chemical conversion process. As a result, an oxide coating film is formed on the surfaces of the second plate portions 22, and the oxide coating film thereby formed becomes a dielectric layer 32 as shown in FIG. 33B.

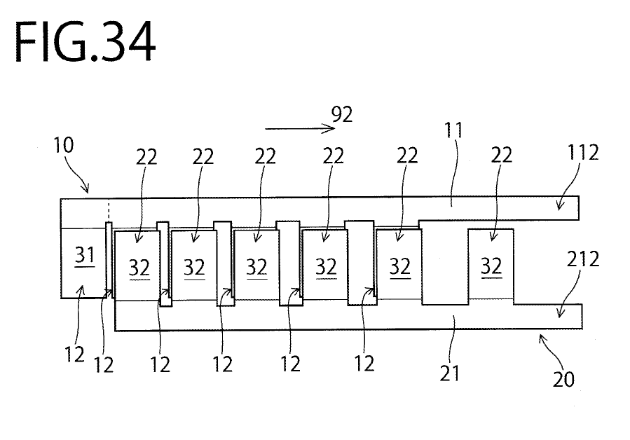

FIG. 34 is a plan view used for explanation of the overlapping step of the sixth embodiment. As shown in FIG. 34, in the overlapping step, first and second electrode sheets 10 and 20 are made to overlap each other such that tip ends of the first plate portions 12 and tip ends of the second plate portions 22 point in opposite directions. At this time, the second electrode sheet 20 is arranged with respect to the first electrode sheet 10 such that none of the second plate portions 22 overlaps one of the first plate portions 12 closest to one edge of the first strip portion 11 in a longitudinal direction 92 (left edge of the first strip portion 11 in the plane of FIG. 34), and that the second plate portions 22 overlap the other first plate portions 12 one by one. Additionally, in the overlapping step of the sixth embodiment, the first and second electrode sheets 10 and 20 are also made to overlap each other such that the first plate portions 12 do not overlap the second strip portion 21, and that the second plate portions 22 do not overlap the first strip portion 11.

Next, the folding step same as that of the fourth embodiment is preformed to complete the formation of the stacked structure 101 shown in FIG. 32.

Like the third and fourth embodiments, the sixth embodiment avoids complicated process of handling the first plate portions 12 and the second plate portions 22 individually. Additionally, as a result of provision of the first plate portion 12 with no second plate portion 22 thereon in the overlapping step, the first plate portions 12 and the second plate portions 22 can be stacked one by one alternately in the folding step by simple technique of folding (winding) the first and second strip portions 11 and 21 in a spiral shape.

Thus, time required for stacking the first plate portions 12 and the second plate portions 22 is shortened, thereby increasing manufacturing efficiency of the stacked capacitor. Further, the stacked capacitor thereby formed has a structure where the first plate portions 12 and the second plate portions 22 are stacked one by one alternately. In this structure, the first strip portion 11 is not placed between any two of the first flat sections 111 adjacent to each other, and the second strip portion 21 is not placed between any two of the second flat sections 211 adjacent to each other. This avoids volume increase of part not contributing to increase in electrostatic capacitance, so that reduction in electrostatic capacitance per unit volume is avoided.

### 7. First Modification

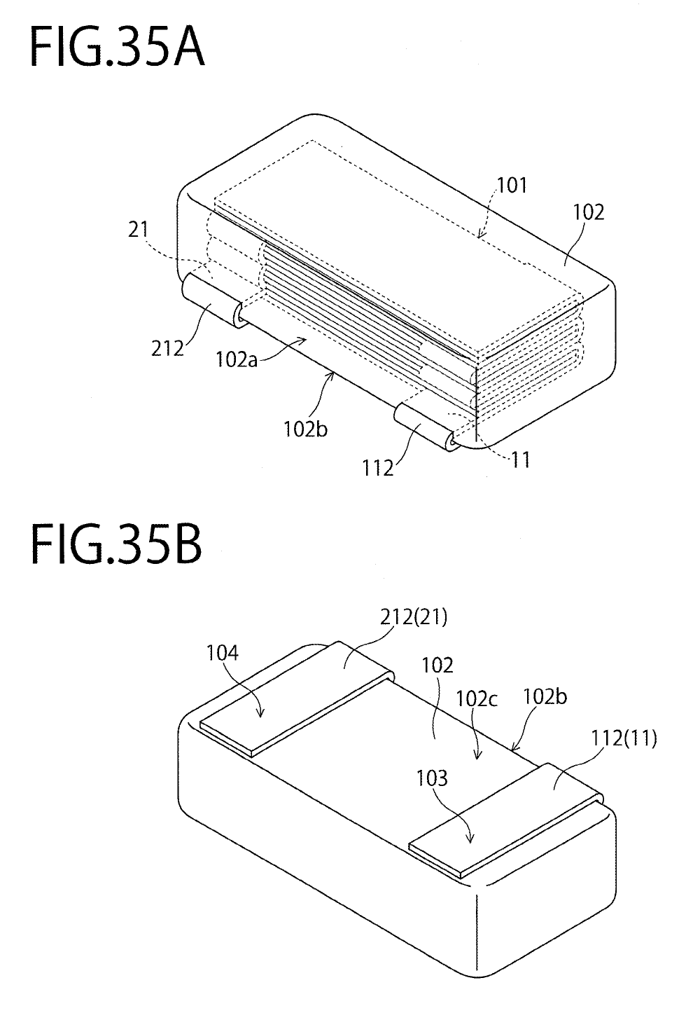

A modification of the stacked capacitor of the first embodiment is described below. FIGS. 35A and 35B are perspective views of a stacked capacitor of a first modification when the stacked capacitor is seen from obliquely above and obliquely below respectively. Regarding the structure of the stacked capacitor of the first modification, a difference from the structure of the first embodiment is described below. The same structure as that of the first embodiment will not be described again. Each constituent element of the stacked capacitor and that of a method of manufacturing the same of the first modification are applicable not only to the stacked capacitor of the first embodiment but also to the stacked capacitor of each of the second to sixth embodiments.

As shown in FIGS. 35A and 35B, the outer package 102 is molded with an electrically insulating material such as an epoxy resin to cover the stacked structure 101. Further, the end section 112 of the first strip portion 11 and the end section 212 of the second strip portion 21 are pulled out of the outer package 102 through its side surface 102a, and passes through a lower edge 102b of the side surface 102a to extend over a lower surface 102c.

In the stacked capacitor of the first modification, part of the end section 112 existing on the lower surface 102c forms the anode terminal 103, and part of the end section 212 existing on the lower surface 102c forms the cathode terminal 104. So, the anode and cathode terminals 103 and 104 become lower surface electrodes of the stacked capacitor.

Regarding the method of manufacturing the stacked capacitor of the first modification, the stacked structure 101 is formed by the same manufacturing method as that of the first embodiment. Then, in the outer package forming step, the outer package 102 is formed by molding with an electrically insulating material such as an epoxy resin to cover the stacked structure 101. At this time, the outer package 102 is formed such that the end section 112 of the first strip portion 11 and the end section 212 of the second strip portion 21 are pulled out of the outer package 102 through the side surface 102a thereof.

In a terminal forming step performed after the outer package forming step, the end sections 112 and 212 are bent to make the end sections 112 and 212 extend along the side and lower surfaces 102a and 102c of the outer package 102, thereby completing the formation of the stacked capacitor shown in FIGS. 35A and 35B.

### 8. Second Modification

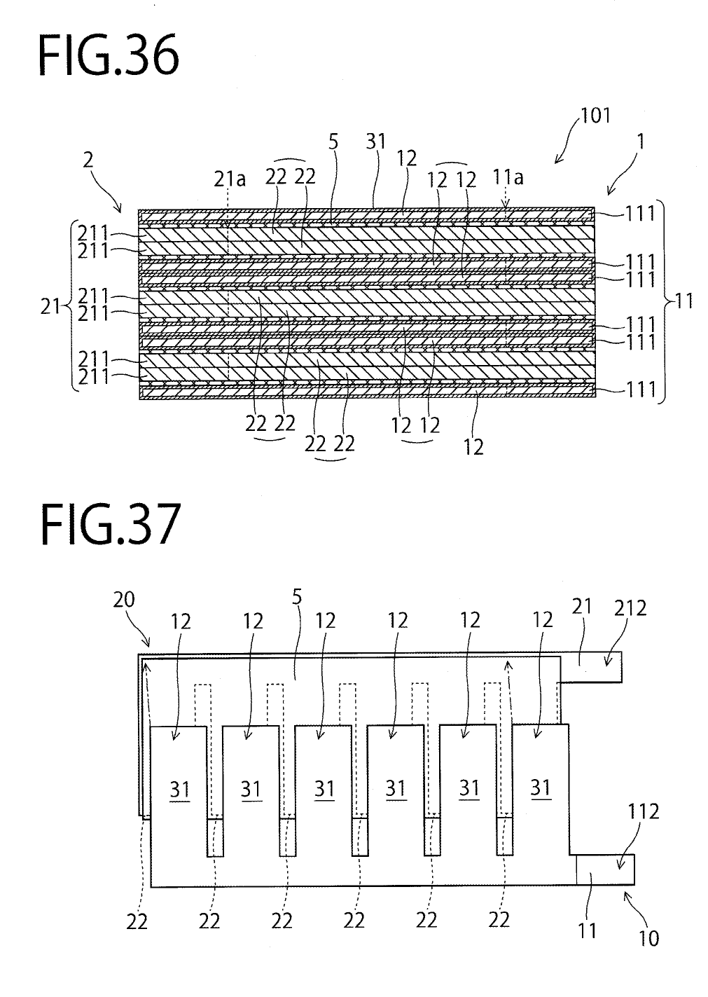

A different modification of the stacked capacitor of the first embodiment is described below. FIG. 36 is a sectional view of a stacked structure 101 of a stacked capacitor of a second modification. The second modification is an example of the case where the invention is applied to an electrolytic capacitor. Regarding the structure of the stacked capacitor of the second modification, a difference from the structure of the first embodiment is described below. The same structure as that of the first embodiment will not be described again. Each constituent element of the stacked capacitor and that of a method of manufacturing the same of the second modification are applicable not only to the stacked capacitor of the first embodiment but also to the stacked capacitor of each of the second to sixth embodiments.

As shown in FIG. 36, the dielectric layer 31 is present on surfaces of the first plate portions 12 and the first flat sections 111, whereas the second dielectric layer 32 is not present on surfaces of the second plate portions 22 and the second flat sections 211. Further, a separator 5 is placed between the dielectric layer 31 and adjacent ones of the second plate portions 22, and the separator 5 is impregnated with an electrolytic solution.

The method of manufacturing the stacked capacitor of the second modification is described next. This manufacturing method includes an electrode sheet forming step, a dielectric layer forming step, an overlapping step, a folding step, and an outer package forming step that are performed sequentially in this order. The electrode sheet forming step and the outer package forming step are the same as those of the first embodiment, so they will not be described again.

Like in the first embodiment, the first electrode sheet 10 is subjected to chemical conversion process in the dielectric layer forming step to form the dielectric layer 31 on the surfaces of the first strip portion 11 and the first plate portions 12. Meanwhile, the second electrode sheet 20 is not subjected to chemical conversion process, so that the dielectric layer 32 is not formed on the surfaces of the second strip portion 21 and the second plate portions 22.

FIG. 37 is a plan view used for explanation of the overlapping step of the second modification. As shown in FIG. 37, in the overlapping step, the first and second electrode sheets 10 and 20 are made to overlap each other while the separator 5 is placed between the first and second electrode sheets 10 and 20. The first and second electrode sheets 10 and 20 are arranged in the same positions with respect to each other as those of the first embodiment.

In the folding step, the first and second strip portions 11 and 21, and the separator 5 are folded together in a bellows shape in the same manner as that of the first embodiment. After the folding step is performed, the separator 5 is impregnated with an electrolytic solution, thereby completing the formation of the stacked structure 101 shown in FIG. 36.

### 9. Third Modification

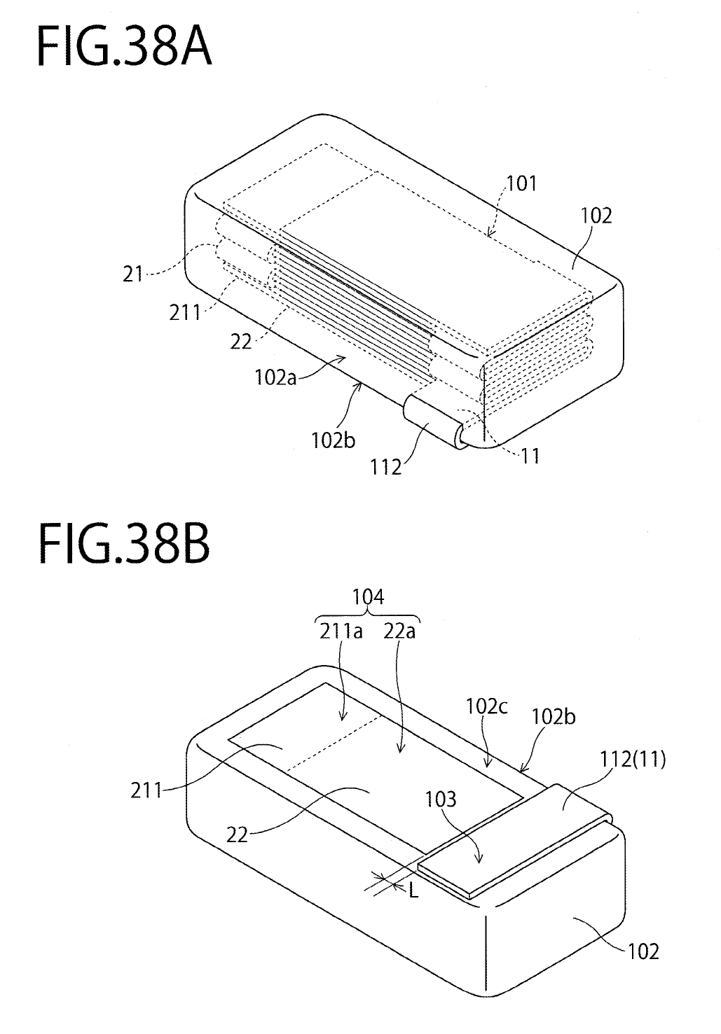

A modification of the stacked capacitor of the fifth embodiment is described below. FIGS. 38A and 38B are perspective views of a stacked capacitor of a third modification when the stacked capacitor is seen from obliquely above and obliquely below respectively. Regarding the structure of the stacked capacitor of the third modification, a difference from the structure of the fifth embodiment is described below. The same structure as that of the fifth embodiment will not be described again. Each constituent element of the stacked capacitor and that of a method of manufacturing the same of the third modification are applicable not only to the stacked capacitor of the fifth embodiment but also to the stacked capacitor of the sixth embodiment.

As shown in FIGS. 38A and 38B, the outer package 102 is molded with an electrically insulating material such as an epoxy resin to cover the stacked structure 101. Further, the end section 112 of the first strip portion 11 is pulled out of the outer package 102 through its side surface 102a, and passes through a lower edge 102b of the side surface 102a to extend over a lower surface 102c. Meanwhile, the second strip portion 21 is not pulled out through the side surface 102a.

Further, in the stacked structure 101, the dielectric layer 32 is not formed on a lower surface 22a of a second plate portion 22 in the bottom layer. So, a conductive material forming the second electrode part 2 is exposed at the lower surface 22a. The lower surface 22a of the second plate portion 22 in the bottom layer and a lower surface 211a of a second flat section 211 from which this second plate portion 22 extends are exposed at the lower surface 102c of the outer package 102.

In the stacked capacitor of the third modification, part of the end section 112 existing on the lower surface 102c forms the anode terminal 103, and the exposed surfaces of the second plate portion 22 and the second flat section 211 (lower surfaces 22a and 211a) form the cathode terminal 104. So, the anode and cathode terminals 103 and 104 become lower surface electrodes of the stacked capacitor.

A method of manufacturing the stacked capacitor of the third modification is described next. This manufacturing method includes an electrode sheet forming step, a masking step, a dielectric layer forming step, an overlapping step, a folding step, an outer package forming step, and a terminal forming step that are performed sequentially in this order.

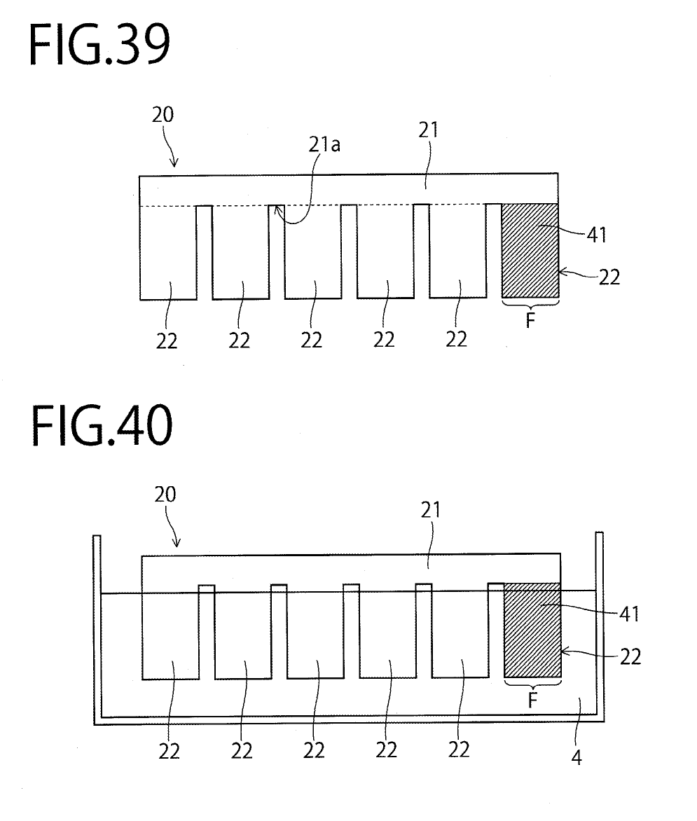

FIG. 39 is a plan view used for explanation of the electrode sheet forming step and the masking step of the third modification. As shown in FIG. 39, the second electrode sheet 20 formed in the electrode sheet forming step is not given the end section 212 of the second strip portion 21. Or, the length of the end section 212 is shortened if the end section 212 is provided. The structure of the first electrode sheet 10 formed in the electrode sheet forming step is the same as that of the fifth embodiment, so it will not be described again.

As shown in FIG. 39, in the masking step, the second electrode sheet 20 is subjected to masking process. More specifically, a region F is covered with an electrically insulating film 41. The region F is a region to become the lower surface 22a of the second plate portion 22 to be placed in the bottom layer of the stacked structure 101 to be formed.

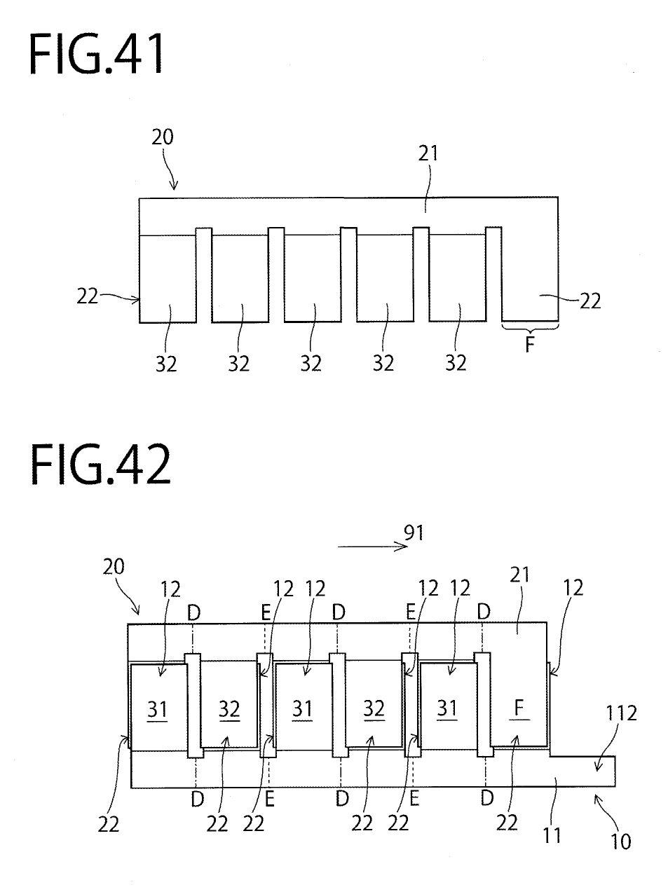

FIG. 40 is a view used for explanation of the dielectric layer forming step of the third modification. As shown in FIG. 40, in the dielectric layer forming step, the second plate portions 22 are dipped in the solution 4 for chemical conversion such as an aqueous solution of boron. In this condition, a voltage is applied between the second electrode sheet 20 and the solution 4 for chemical conversion. As a result, an oxide coating film is formed in a region of surfaces of the second plate portions 22 not covered with the electrically insulating film 41, and the oxide coating film thereby formed becomes the dielectric layer 32 as shown in FIG. 41. Meanwhile, the oxide coating film is not formed in the region F covered with the electrically insulating film 41, so that the conductive material forming the second electrode sheet 20 remains exposed in the region F. The dielectric layer 31 is formed on the first electrode sheet 10 in the same manner as that of the fifth embodiment.

FIG. 42 is a plan view used for explanation of the overlapping step of the third modification. As shown in FIG. 42, in the overlapping step, the first and second electrode sheets 10 and 20 are made to overlap each other in the same manner as that of the fifth embodiment. Meanwhile, in the overlapping step of the third modification, the second electrode sheet 20 is arranged with respect to the first electrode sheet 10 such that none of the first plate portions 12 overlaps the region F of the second plate portion 22.

In the folding step, the first and second strip portions 11 and 21 are folded together in a bellows shape such that none of the first plate portions 12 overlaps the region F of the second plate portion 22. More specifically, the first and second strip portions 11 and 21 are mountain folded together at three positions along lines D (dashed-dotted lines) shown in FIG. 42, and are valley folded together at two positions along lines E (dashed lines) shown in FIG. 42. As a result of execution of the folding step, the formation of the stacked structure 101 of the third modification is completed.

In the outer package forming step, the outer package 102 is formed by molding with an electrically insulating material such as an epoxy resin to cover the stacked structure 101. At this time, the outer package 102 is formed such that the end section 112 of the first strip portion 11 is pulled out of the outer package 102 through the side surface 102a, and that the lower surface 22a (region F) of the second plate portion 22 and the lower surface 211a of the second flat section 211 are exposed at the lower surface 102c (see FIG. 38B).

In the terminal forming step, the end section 112 is bent to make the end section 112 extend along the side and lower surfaces 102a and 102c of the outer package 102, thereby completing the formation of the stacked capacitor shown in FIGS. 38A and 38B.

The stacked capacitor of the third modification shortens a distance L between the anode and cathode terminals 103 and 104 (see FIG. 38B), thereby reducing the ESL (equivalent series inductance) of the stacked capacitor.

### 10. Fourth Modification

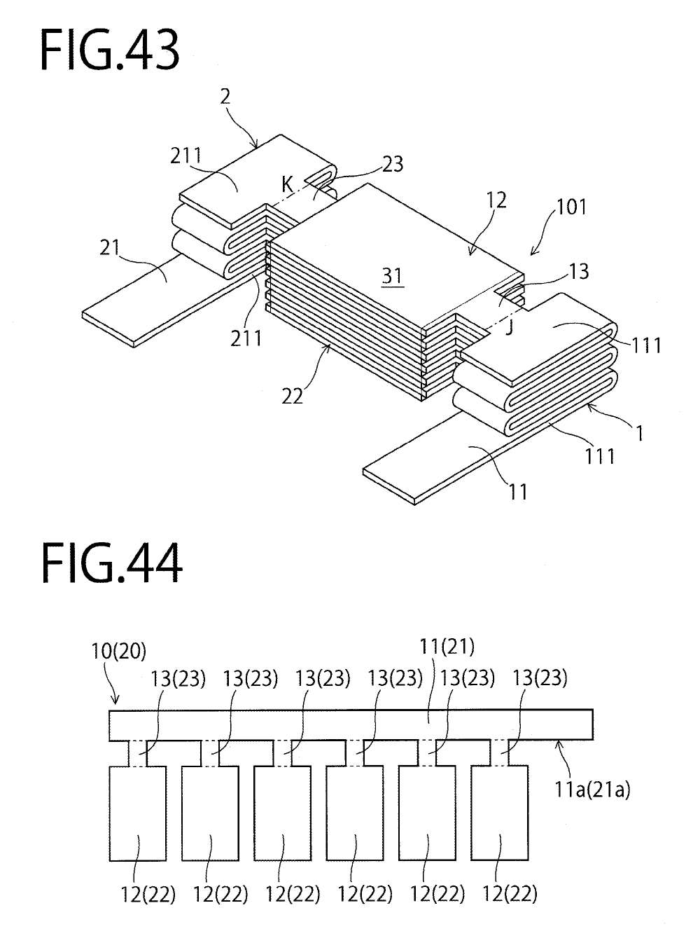

A different modification of the stacked capacitor of the fifth embodiment is described below. FIG. 43 is a perspective view of a stacked structure 101 of a stacked capacitor of a fourth modification. Regarding the structure of the stacked capacitor of the fourth modification, a difference from the structure of the fifth embodiment is described below. The same structure as that of the fifth embodiment will not be described again. Each constituent element of the stacked capacitor and that of a method of manufacturing the same of the fourth modification are applicable not only to the stacked capacitor of the fifth embodiment but also to the stacked capacitor of the sixth embodiment.

As shown in FIG. 43, drawer portions 13 smaller in width than the first plate portions 12 extend from corresponding ones of the first flat sections 111 of the first strip portion 11. The first plate portions 12 are formed at tip ends of corresponding ones of drawer portions 13. Further, drawer portions 23 smaller in width than the second plate portions 22 extend from corresponding ones of the second flat sections 211 of the second strip portion 21. The second plate portions 22 are formed at tip ends of corresponding ones of the drawer portions 23.

In a method of manufacturing the stacked capacitor of the fourth modification, the first and second electrode sheets 10 and 20 formed in the electrode sheet forming step have structures difference from those of the fifth embodiment (see FIG. 6). More specifically, as shown in FIG. 44, the first electrode sheet 10 includes the first strip portion 11, the plurality of drawer portions 13 extending in the form of comb teeth from the side edge 11a of the first strip portion 11, and the plurality of first plate portions 12 formed at the tip ends of corresponding ones of the drawer portions 13. Further, the second electrode sheet 20 includes the second strip portion 21, the plurality of drawer portions 23 extending in the form of comb teeth from the side edge 21a of the second strip portion 21, and the plurality of second plate portions 22 formed at the tip ends of corresponding ones of the drawer portions 23. The manufacturing method of the fourth modification is the same in other respects as that of the fifth embodiment, so it will not be described again.

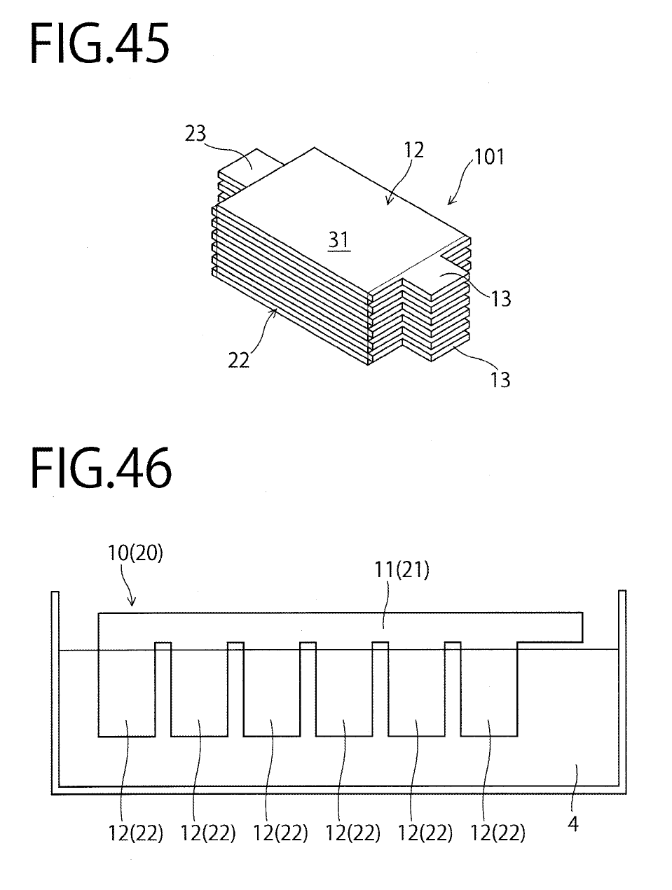

FIG. 45 is a perspective view of a different example of the stacked structure 101. As shown in FIG. 45, the first and second strip portions 11 and 21 may be omitted in the stacked structure 101. This stacked structure 101 is formed by cutting the drawer portions 13 and 23 of the stacked structure 101 shown in FIG. 43 along a line J and a line K (dashed-dotted lines) shown in FIG. 43 respectively. In a stacked capacitor with the stacked structure 101 shown in FIG. 45, an external electrode (not shown in the drawings) to become the anode terminal 103 is electrically connected to the drawer portions 13. Further, an external electrode (not shown in the drawings) to become the cathode terminal 104 is electrically connected to the drawer portions 23.

### 11. Examples

For formation of the stacked capacitor of each of the first to sixth embodiments, the following conditions are applicable for the electrode sheet forming step and the dielectric layer forming step.

In the electrode sheet forming step, an aluminum foil of a thickness of 30 μm is prepared. Then, the aluminum foil is die-cut such that the first strip portion 11 has a width of 5 mm, and that the length and the width of each of the first plate portions 12 are 20 mm and 10 mm respectively, thereby forming the first electrode sheet 10. The aluminum foil is further die-cut such that the second strip portion 21 has a width of 5 mm, and that the length and the width of each of the second plate portions 22 are 20 mm and 10 mm respectively, thereby forming the second electrode sheet 20.

In the dielectric layer forming step, the first and second electrode sheets 10 and 20 are first subjected to hydration process with pure water for 10 minutes at a temperature of 95° C. Then, for formation of the stacked capacitor of each of the first to fourth embodiments, part of the first electrode sheet 10 except the end section 112 of the first strip portion 11 is dipped in a 10 percent aqueous solution of boron (at a temperature of 95° C.) being the solution 4 for chemical conversion (see FIG. 7). Meanwhile, for formation of the stacked capacitor of each of the fifth and sixth embodiments, parts of the first plate portions 12 of a length of 15 mm from their tip ends are dipped in the 10 percent aqueous solution of boron (at a temperature of 95° C.) (see FIG. 29). Under these conditions, a constant voltage of 250 V is applied between the first electrode sheet 10 and the solution 4 for chemical conversion to electrochemically oxidize a surface of the part of the first electrode sheet 10 dipped in the solution 4 for chemical conversion (anodic oxidation) for 20 minutes. The second electrode sheet 20 is subjected to the same oxidation process as that on the first electrode sheet 10.

Next, the first and second electrode sheets 10 and 20 are cleaned with pure water for 10 minutes. Then, the first and second electrode sheets 10 and 20 are subjected to thermal process for two minutes at a temperature of 500° C. The aforementioned oxidation process is performed again on the first and second electrode sheets 10 and 20 for five minutes. The first and second electrode sheets 10 and 20 are thereafter cleaned with pure water for 10 minutes. Next, the first and second electrode sheets 10 and 20 are dried at a temperature of 100° C. for 10 minutes.

If the stacked capacitor of each of the first to sixth embodiments is formed under the aforementioned conditions to have six first plate portions 12 and six second plate portions 22, a total of the facing areas of the electrode pairs is determined in each stacked capacitor as follows.

Regarding the stacked capacitor of each of the first to fourth embodiments, the facing area per electrode pair is determined as 25×10 mm². In the stacked capacitor of the first embodiment, six electrode pairs are formed so a total of the facing areas is determined as 25×10×6 mm² (Example 1). In the stacked capacitor of the second embodiment, 11 electrode pairs are formed so a total of the facing areas is determined as 25×10×11 mm² (Example 2). In the stacked capacitor of the third embodiment, 10 electrode pairs are formed so a total of the facing areas is determined as 25×10×10 mm² (Example 3). In the stacked capacitor of the fourth embodiment, 11 electrode pairs are formed so a total of the facing areas is determined as 25×10×11 mm² (Example 4).

Regarding the stacked capacitor of each of the fifth and sixth embodiments, the facing area per electrode pair is determined as 15×10 mm². In the stacked capacitor of each of the fifth and sixth embodiments, 11 electrode pairs are formed so a total of the facing areas is determined as 15×10×11 mm² (Example 5).

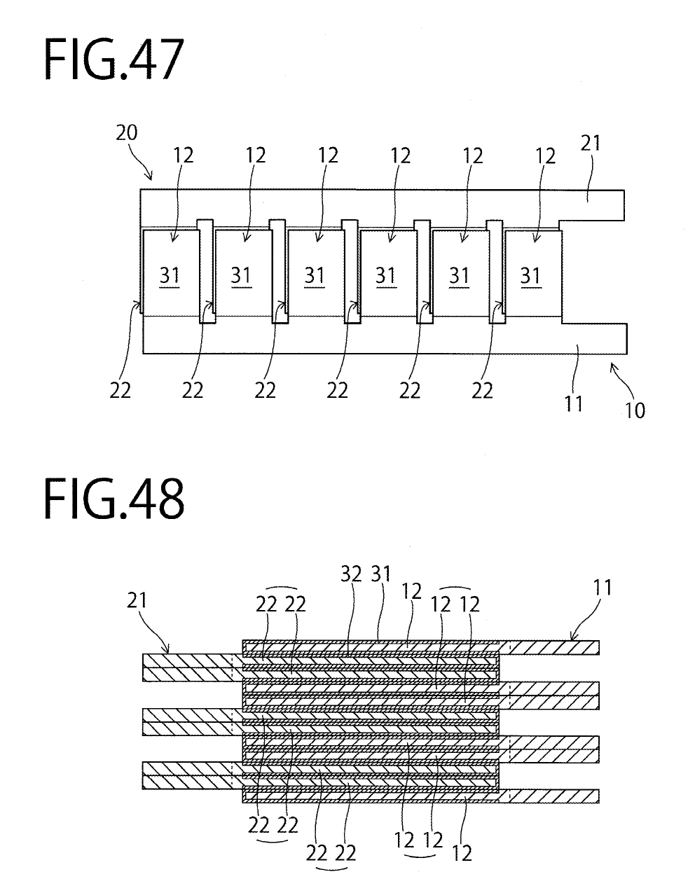

A stacked capacitor formed in the following manner is given as Comparative Example. First, as shown in FIG. 46, parts of the first plate portions 12 of a length of 15 mm from their tip ends is dipped in a 10 percent aqueous solution of boron (at a temperature of 95° C.) being the solution 4 for chemical conversion. Under this condition, the first electrode sheet 10 is subjected to oxidation process to form the dielectric layer 31. The second electrode sheet 20 is subjected to the same oxidation process as that on the first electrode sheet 10. Next, as shown in FIG. 47, the first and second electrode sheets 10 and 20 are made to overlap each other such that the second plate portions 22 overlap the first plate portions 12 one by one from the same direction, At this time, the first and second electrode sheets 10 and 20 are made to overlap each other such that the first plate portions 12 do not overlap the second strip portion 21, and that the second plate portions 22 do not overlap the first strip portion 11.

Next, the first and second strip portions 11 and 21 are folded together in a bellows shape to stack the first plate portions 12 and the second plate portions 22 (Comparative Example 1). Or, the first and second strip portions 11 and 21 are folded together in a spiral shape to stack the first plate portions 12 and the second plate portions 22 (Comparative Example 2).

FIG. 48 is a sectional view of a stacked structure of a stacked capacitor of Comparative Example 1. As shown in FIG. 48, in the stacked capacitor of Comparative Example 1, two of the first plate portions 12 and two of the second plate portions 22 are stacked alternately in inner layers (layers except the top and bottom layers). So, if the stacked capacitor of Comparative Example 1 is formed under the aforementioned conditions to have six first plate portions 12 and six second plate portions 22, the capacitor is provided with six electrode pairs, and a total of the facing areas is determined as 15×10×6 mm².

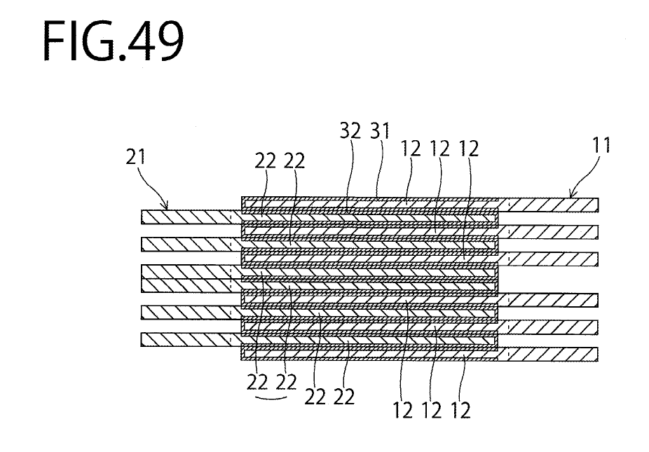

FIG. 49 is a sectional view of a stacked structure of a stacked capacitor of Comparative Example 2. As shown in FIG. 49, in the stacked capacitor of Comparative Example 2, two of the second plate portions 22 overlap each other, and the first plate portions 12 and the other second plate portions 22 are placed one by one alternately in upper layers and lower layers with respect to the two overlapping second plate portions 22. So, if the stacked capacitor of Comparative Example 2 is formed under the aforementioned conditions to have six first plate portions 12 and six second plate portions 22, the capacitor is provided with 10 electrode pairs, and a total of the facing areas is determined as 15×10×10 mm².

The total of the facing areas of each of Examples 1 to 5 and Comparative Example 2 is compared to that of Comparative Example 1. These totals are 1.67 times, 3.06 times, 2.78 times, 3.06 times, 1.83 times, and 1.67 times, respectively, that of Comparative Example 1. This result shows that the stacked capacitor including the stacked structure of the invention increases an electrostatic capacitance compared to the stacked capacitor of Comparative Example 1, and that the stacked capacitor of each of the second to fourth embodiments increases an electrostatic capacitance significantly.

The structure of each part of the invention is not limited to that shown in the embodiments described above. Various modifications can be devised without departing from the technical scope recited in claims. As an example, in the aforementioned stacked structure 101, an anode part of an electrode may be composed of the second electrode part 2 and a cathode part of the electrode may be composed of the first electrode part 1. Further, each constituent element of the aforementioned stacked structure 101 and that of a method of manufacturing the same are applicable to various types of stacked capacitors including a stacked ceramic capacitor and a stacked electrolytic capacitor. Additionally, each constituent element of the aforementioned stacked structure 101 and that of a method of manufacturing the same are also applicable to stacked structures of the followings devices: a battery such as a secondary battery, a capacitor including a conductive polymer as an electrolyte, a capacitor including a conductive polymer and an electrolytic solution, an electric double-layer capacitor, and the like.

1. A stacked structure, comprising:
a first electrode part with a first strip portion and a plurality of first plate portions extending from a side edge of the first strip portion;
a second electrode part with a second strip portion and a plurality of second plate portions extending from a side edge of the second strip portion; and
a dielectric layer,
the first and second electrode parts being arranged such that the first plate portions and the second plate portions are stacked, the first plate portions facing the second plate portions and the second strip portion, the second plate portions facing the first plate portions and the first strip portion,
the dielectric layer being placed between the first plate portions and adjacent ones of the second plate portions, between the first plate portions and the second strip portion, and between the second plate portions and the first strip portion.

2. The stacked structure according to claim 1, wherein
the first strip portion has a bellows shape or a spiral shape, the first strip portion has a plurality of first flat sections, and each of the first plate portions extends from a corresponding one of the first flat sections,
the second strip portion has a bellows shape or a spiral shape, the second strip portion has a plurality of second flat sections, and each of the second plate portions extends from a corresponding one of the second flat sections,
the first and second electrode parts are arranged such that the first plate portions and the second plate portions are stacked one by one alternately,
each of the second plate portions is placed partially between corresponding two of the first flat sections adjacent to each other while the first strip portion is not placed between the two adjacent first flat sections, and
each of the first plate portions is placed partially between corresponding two of the second flat sections adjacent to each other while the second strip portion is not placed between the two adjacent second flat sections.

3. A method of manufacturing a stacked structure, comprising the steps of:
(a) forming a first electrode sheet with a first strip portion and a plurality of first plate portions extending in the form of comb teeth from a side edge of the first strip portion;
(b) forming a second electrode sheet with a second strip portion and a plurality of second plate portions extending in the form of comb teeth from a side edge of the second strip portion;
(c) forming a dielectric layer on surfaces of at least the first plate portions or the second plate portions, and on a surface of at least the first or second strip portion;
(d) making the first and second electrode sheets overlap each other to determine the arrangement of the second electrode sheet with respect to the first electrode sheet such that the second plate portions overlap the first plate portions, and that regarding each of the first plate portions and one of the second plate portions to overlap this first plate portion, part of this first plate portion overlaps the second strip portion and part of this second plate portion overlaps the first strip portion, the step (d) being performed after the steps (a) to (c); and
(e) folding the first and second strip portions together in a bellows shape or a spiral shape to stack the first plate portions and the second plate portions, the step (e) being performed after the step (d).

4. The method according to claim 3, wherein
in the step (d), the second electrode sheet is also arranged with respect to the first electrode sheet such that the second plate portions overlap the first plate portions one by one, and that upper and lower positions of the first plate portions and the second plate portions with respect to each other are changed alternately in a longitudinal direction of the first or second strip portion, and
in the step (e), the first and second strip portions are folded together in a bellows shape to place each of the first plate portions and a corresponding one of the second plate portions one above the other in facing positions, this first plate portion and the corresponding second plate portion having been adjacent to each other in the longitudinal direction.

5. The method according to claim 3, wherein
in the step (d), the second electrode sheet is also arranged with respect to the first electrode sheet such that none of the second plate portions overlaps one of the first plate portions closest to one edge of the first strip portion in a longitudinal direction of the first strip portion, and that the second plate portions overlap the other first plate portions one by one, and
in the step (e), the first and second strip portions are folded together in a spiral shape, so that the first plate portion with no second plate portion thereon is first placed on an adjacent one of the second plate portions, and then the first plate portions are successively placed on adjacent ones of the second plate portions.

6. The method according to claim 5, wherein
in the first electrode sheet formed in the step (a), a distance between two of the first plate portions adjacent to each other is set to become greater gradually with progress in the longitudinal direction of the first strip portion, and
in the second electrode sheet formed in the step (b), a distance between two of the second plate portions adjacent to each other is set to become greater gradually with progress in a longitudinal direction of the second strip portion.

7. A stacked structure, comprising:
a first electrode part with a first strip portion and a plurality of first plate portions extending from a side edge of the first strip portion;
a second electrode part with a second strip portion and a plurality of second plate portions extending from a side edge of the second strip portion; and
a dielectric layer,
the first and second strip portions each having a bellows shape or a spiral shape, the first and second electrode parts being arranged such that the first plate portions and the second plate portions are stacked one by one alternately, the dielectric layer being placed between the first plate portions and adjacent ones of the second plate portions,
the first strip portion having a plurality of first flat sections, each of the first plate portions extending from a corresponding one of the first flat sections, the first strip portion being not placed between any two of the first flat sections adjacent to each other,
the second strip portion having a plurality of second flat sections, each of the second plate portions extending from a corresponding one of the second flat sections, the second strip portion being not placed between any two of the second flat sections adjacent to each other.

8. The stacked structure according to claim 7, wherein
each of the first plate portions faces one of the second plate portions stacked thereon and one of the second flat sections from which this second plate portion extends,
each of the second plate portions faces one of the first plate portions stacked thereon and one of the first flat sections from which this first plate portion extends, and
the dielectric layer is placed between the first plate portions and adjacent ones of the second plate portions, between the first plate portions and adjacent ones of the second flat sections, and between the second plate portions and adjacent ones of the first flat sections.

9. A method of manufacturing a stacked structure, comprising the steps of:
(a) forming a first electrode sheet with a first strip portion and a plurality of first plate portions extending in the form of comb teeth from a side edge of the first strip portion;
(b) forming a second electrode sheet with a second strip portion and a plurality of second plate portions extending in the form of comb teeth from a side edge of the second strip portion;
(c) forming a dielectric layer on surfaces of at least the first plate portions or the second plate portions;
(d) making the first and second electrode sheets overlap each other to determine the arrangement of the second electrode sheet with respect to the first electrode sheet such that the second plate portions overlap the first plate portions one by one, and that upper and lower positions of the first plate portions and the second plate portions with respect to each other are changed alternately in a longitudinal direction of the first or second strip portion, the step (d) being performed after the steps (a) to (c); and
(e) folding the first and second strip portions together in a bellows shape to place each of the first plate portions and a corresponding one of the second plate portions one above the other in facing positions, this first plate portion and the corresponding second plate portion having been adjacent to each other in the longitudinal direction, the step (e) being performed after the step (d).

10. The method according to claim 9, wherein
in the step (c), the dielectric layer is further formed on a surface of at least the first or second strip portion, and
in the step (d), the second electrode sheet is also arranged with respect to the first electrode sheet such that regarding each of the first plate portions and one of the second plate portions to overlap this first plate portion, part of this first plate portion overlaps the second strip portion and part of this second plate portion overlaps the first strip portion.

11. A method of manufacturing a stacked structure, comprising the steps of:
(a) forming a first electrode sheet with a first strip portion and a plurality of first plate portions extending in the form of comb teeth from a side edge of the first strip portion;
(b) forming a second electrode sheet with a second strip portion and a plurality of second plate portions extending in the form of comb teeth from a side edge of the second strip portion;
(c) forming a dielectric layer on surfaces of at least the first plate portions or the second plate portions;
(d) making the first and second electrode sheets overlap each other to determine the arrangement of the second electrode sheet with respect to the first electrode sheet such that none of the second plate portions overlaps one of the first plate portions closest to one edge of the first strip portion in a longitudinal direction of the first strip portion, and that the second plate portions overlap the other first plate portions one by one, the step (d) being performed after the steps (a) to (c); and
(e) folding the first and second strip portions together in a spiral shape, so that the first plate portion with no second plate portion thereon is first placed on an adjacent one of the second plate portions, and then the first plate portions are successively placed on adjacent ones of the second plate portions, the step (e) being performed after the step (d).

12. The method according to claim 11, wherein
in the first electrode sheet formed in the step (a), a distance between two of the first plate portions adjacent to each other is set to become greater gradually with progress in the longitudinal direction of the first strip portion, and
in the second electrode sheet formed in the step (b), a distance between two of the second plate portions adjacent to each other is set to become greater gradually with progress in a longitudinal direction of the second strip portion.

13. The method according to claim 11, wherein
in the step (c), the dielectric layer is further formed on a surface of at least the first or second strip portion, and
in the step (d), the second electrode sheet is also arranged with respect to the first electrode sheet such that regarding each of the first plate portions and one of the second plate portions to overlap this first plate portion, part of this first plate portion overlaps the second strip portion and part of this second plate portion overlaps the first strip portion.
